(19) United States
(12) Patent Application Publication
(10) Pub. No.: US 2025/0359360 A1
(43) Pub. Date: Nov. 20, 2025

(54) IMAGE SENSOR INCLUDING A SINGLE-PHOTON AVALANCHE DIODE AND METHOD OF MANUFACTURING THE SAME

(71) Applicant: SAMSUNG ELECTRONICS CO., LTD., SUWON-SI (KR)

(72) Inventors: Ikuo Mizuno, Suwon-si (KR); Yoshiharu Kudo, Suwon-si (KR)

(21) Appl. No.: 19/196,156

(22) Filed: May 1, 2025

(30) Foreign Application Priority Data
May 20, 2024 (JP) 2024-081552
Sep. 27, 2024 (KR) 10-2024-0132007

(51) Int. Cl. H10F 30/225; H10F 39/00

(52) U.S. Cl. CPC H10F 30/225; H10F 39/014; H10F 39/802; H10F 39/811

(57) ABSTRACT

An image sensor includes a plurality of single-photon avalanche diode (SPAD) elements formed in a substrate. Each of the plurality of SPAD elements includes a trench separating the SPAD element from another SPAD element, a first semiconductor layer formed on a sidewall of the trench, an insulating film formed inside the trench and covering a portion of the first semiconductor layer, and a first electrode formed inside the trench, the first electrode including a non-contact portion and a first electrode end portion, the non-contact portion being surrounded by the insulating film and not in contact with the first conductivity type semiconductor layer, and the first electrode end portion being in contact with the first conductivity type semiconductor layer and forming a first contact of each of the plurality of SPAD elements.

### CROSS-REFERENCE TO RELATED APPLICATIONS

This application claims priority under 35 U.S.C. § 119 to Japan Patent Application No. 2024-081552, filed on May 20, 2024, in the Japan Patent Office, and is related to Korean Patent Application No. 10-2024-0132007, filed on Sep. 27, 2024, in the Korean Intellectual Property Office, the disclosures of the prior applications are incorporated by reference herein in their entireties.

### BACKGROUND

The inventive concept relates to an image sensor including a single-photon avalanche diode (SPAD) and a method of manufacturing the same.

The SPAD, upon receiving incident light, amplifies charge generated in a photoelectric conversion region of the SPAD and converts the amplified charge into an electrical signal. Because the SPAD may detect individual photon of the incident light, the SPAD features extremely high resolution.

For amplifying the charge, the SPAD may operate in a strong reverse bias state to induce an avalanche amplification. The avalanche amplification may be induced by applying a high reverse bias voltage to a PN-junction of the SPAD. Because high reverse bias voltage is applied to the PN-junction and a power contact of the SPAD is close to the PN-junction, a strong electric field may be established between the PN-junction and the power contact. The strong electric field may cause a tunnel current between the PN-junction and the power contact. The tunnel current may be multiplied in a dark area even where the incident light does not reach, and may become a source of noise and be detected as a false signal.

### SUMMARY

According to an embodiment of the present inventive concept, an image sensor includes a single-photon avalanche diode (SPAD) elements formed in a substrate, and each of the plurality of SPAD elements includes a trench formed in a lattice pattern for separating each of the plurality of SPAD elements, a first semiconductor layer formed on a sidewall of the trench, the first semiconductor layer being a first conductivity type, an insulating film formed on a portion of the first semiconductor layer, and a first electrode formed in the trench, the first electrode including a non-contact portion and a first electrode end portion, wherein the non-contact portion is surrounded by the insulating film and not in contact with the first semiconductor layer, and the first electrode end portion is connected with the non-contact portion and in contact with the first semiconductor layer.

According to an embodiment of the present inventive concept, a method of manufacturing an image sensor comprises forming a trench in a pattern for separating each of the plurality of single-photon avalanche diode (SPAD) elements formed in a substrate, forming a first semiconductor layer on a sidewall of the trench, in which the first semiconductor layer has a first conductivity type, forming an insulating film in the trench, the insulating film covering a portion of the first semiconductor layer, forming a non-contact portion of a first electrode in a portion of the trench, the non-contact portion of the first electrode being in contact with the insulating film, and forming a first electrode end portion in contact with the first semiconductor layer and the non-contact portion of the first electrode, wherein a first contact is formed between the electrode end portion and the first semiconductor layer.

According to an embodiment of the present inventive concept, a method of manufacturing an image sensor comprises forming a trench in a lattice pattern for separating each of the plurality of single-photon avalanche diode (SPAD) elements formed in a substrate, forming a first semiconductor layer on a sidewall of the trench, in which the first semiconductor layer has a first conductivity type, forming a first electrode end portion in a portion of the trench in contact with the first semiconductor layer, in which a first contact is formed between the electrode end portion and the first semiconductor layer, forming an insulating film in the trench, the insulating film covering a portion of the first semiconductor layer and the first electrode end portion, exposing the first electrode end portion by etching back the insulating film, and forming a non-contact portion of a first electrode, the non-contact portion being in contact with the first electrode end portion.

### BRIEF DESCRIPTION OF THE DRAWINGS

Embodiments will be more clearly understood from the following detailed description taken in conjunction with the accompanying drawings in which:

FIG. 1 is a block diagram illustrating a schematic configuration of an image sensor;

FIG. 2 is a circuit diagram illustrating an example of a schematic configuration of a single-photon avalanche diode (SPAD) pixel;

FIG. 3 is a diagram illustrating a stack structure of a pixel array;

FIG. 4 is a cross-sectional view illustrating the structure of a SPAD pixel;

FIG. 5A is a plan view of the plane A-A in FIG. 4 according to an embodiment;

FIG. 5B is a plan view of the plane A-A in FIG. 4 according to an embodiment;

FIGS. 6 to 16 are diagrams illustrating a method of manufacturing an image sensor;

FIG. 17 is a flowchart illustrating a process for manufacturing an image sensor;

FIGS. 18A to 22B are diagrams illustrating a method of manufacturing an image sensor;

FIG. 23 is a flowchart illustrating a process for manufacturing an image sensor;

FIG. 24 is a cross-sectional view illustrating a structure of a SPAD pixel;

FIG. 25 is a cross-sectional view illustrating a structure of a SPAD pixel;

FIGS. 26 to 31 are diagrams illustrating a method of manufacturing an image sensor;

FIG. 32 is a flowchart illustrating a process for manufacturing an image sensor;

FIG. 33 is a cross-sectional view illustrating the structure of a SPAD pixel;

FIG. 34 is a plan view of the plane A-A in FIG. 33;

FIGS. 35 to 38 are diagrams illustrating a process for manufacturing an image sensor;

FIG. 39 is a flowchart illustrating a process for manufacturing an image sensor;

FIG. 40 is a cross-sectional view illustrating the structure of a SPAD pixel;

FIG. 41 is a cross-sectional view illustrating the structure of a SPAD pixel;

FIG. 42 is a plan view of the plane A-A in FIG. 41;

FIG. 43 is a flowchart illustrating a process for manufacturing an image sensor; and

FIG. 44 is a cross-sectional view illustrating the structure of a SPAD pixel.

### DETAILED DESCRIPTION OF THE EMBODIMENTS

Hereinafter, embodiments of an image sensor and a method of manufacturing the image sensor are described in detail based on the accompanying drawings. The embodiments may be modified in various different forms. In the drawings, like reference characters or numerals denote like elements, and the size of each element is expressed in a different ratio from the actual size for clarity and convenience of description.

The expression “on” may include a case where one element is in contact with another element in any direction and a case where one element is located in any direction without being in contact with another element.

Such terms “first,” “second,” and “third” may be used to describe various elements to distinguish one element from another. The terms do not limit the material or structure of elements.

The singular forms “a,” “an,” and “the” are intended to include the plural forms as well, unless the context clearly indicates otherwise. When a portion “includes” an element, another element may be further included, rather than excluding the existence of the other element, unless otherwise described.

As used herein, terminology such as “part” may indicate a unit which processes at least one function or operation and may be implemented by hardware, software, or a combination thereof.

The term “end” or “end portion” may indicate an edge in a certain direction.

Although a first conductivity type is describe to indicate a P-type and a second conductivity type is described to indicate an N-type, the first conductivity type may be the N-type and the second conductivity type may be the P-type.

According to a related art, an image sensor may include a first trench formed in a lattice pattern and a second trench along the bottom of the first trench in a first surface of a semiconductor substrate. The first surface of the semiconductor substrate may include a plurality of photoelectric conversion elements. Each photoelectric conversion element includes a photoelectric conversion region, which generates charge by performing photoelectric conversion of light incident to the photoelectric conversion region. Each photoelectric conversion element includes a first semiconductor region surrounding the photoelectric conversion region, a first contact on the bottom of the first trench and in contact with the first semiconductor region, and a first electrode in the first trench and in contact with the first contact. Each photoelectric conversion element includes a second semiconductor region in contact with the first semiconductor region, and the second semiconductor region has a first conductivity type that is the same as the first semiconductor region. Each photoelectric conversion element includes a third semiconductor region in contact with the second semiconductor region. The third semiconductor region is disposed between the second semiconductor region and the first surface, and has a second conductivity type opposite to the first conductivity type. Each photoelectric conversion element includes a second contact, which is arranged on the first surface in contact with the third semiconductor region, and a second electrode in contact with the second contact. The height of the first contact from the first surface is different from the height of the third semiconductor region from the first surface.

According to the related art, the width of the first trench needs to be greater than the width of the second trench because a power contact is formed on the bottom of the first trench between two trenches connected in series to each other. In addition, because a PN-junction needs to be distant from the power contact to prevent tunnel current, it is necessary to increase the depth of the first trench from the first surface. However, as the depth of the first trench increases, the width of the first trench also increases. Accordingly, the photon detection efficiency (PDE) of the SPAD may be degraded because effective size of the photoelectric conversion region becomes smaller due to the increased width of the first trench.

According to an embodiment of the present inventive concept, an image sensor includes a plurality of single-photon avalanche diode (SPAD) elements formed in a substrate. Each of the plurality of SPAD elements includes a trench separating each of the SPAD element from other SPAD elements of the plurality of SPAD elements, a first semiconductor layer formed on a sidewall of the trench, an insulating film formed inside the trench and covering a portion of the first semiconductor layer, and a first electrode formed inside the trench. The first electrode includes a non-contact portion and a first electrode end portion, and the non-contact portion is surrounded by the insulating film and not in contact with the first conductivity type semiconductor layer, and the first electrode end portion is in contact with the first conductivity type semiconductor layer and form a first contact of each of the plurality of SPAD elements.

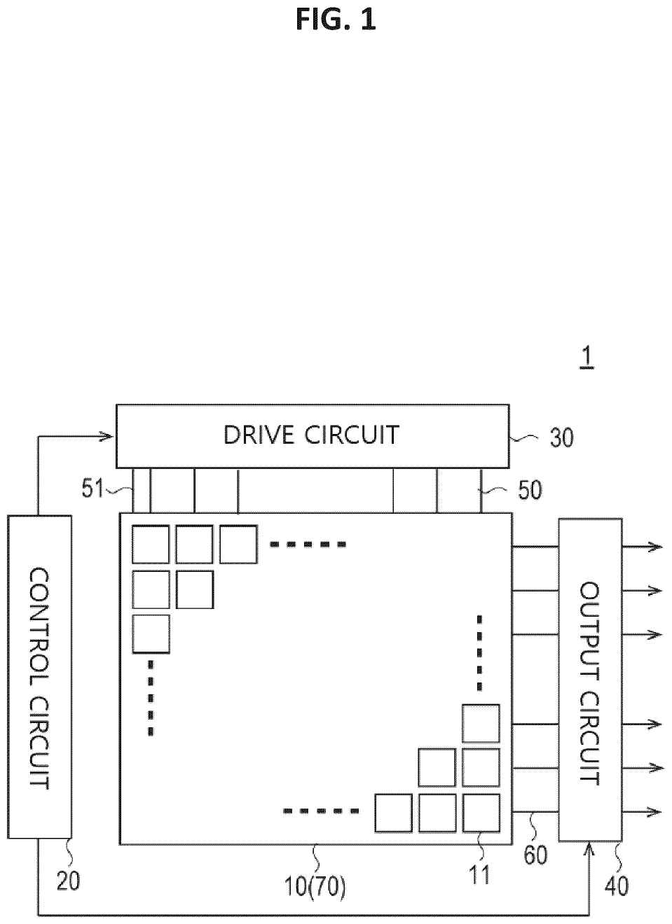

FIG. 1 is a block diagram illustrating a schematic configuration of an image sensor 1. The image sensor 1 may be a backside illumination image sensor or a surface illumination image sensor depending on whether a device formation surface receives incident light or a surface opposite to the device formation surface receives incident light. The backside illumination image sensor may receive the incident light onto a surface of a semiconductor substrate 510 opposite to the device formation surface of the semiconductor substrate 510a. In the surface illumination image sensor, a device formation surface may receive the incident light, in which the device formation surface is also a light incident surface. Hereinafter, although the backside illumination image sensor is described as an embodiment of the image sensor 1, the present inventive concept may also be applied to the surface illumination image sensor.

The image sensor 1 may include a pixel array 10, a control circuit 20, a drive circuit 30, and an output circuit 40.

The pixel array 10 may include a plurality of single-photon avalanche diode (SPAD) pixels 11 in a matrix form. A pixel drive line 50 is connected to each column of SPAD pixels 11, and an output signal line 60 is connected to each row of SPAD pixels 11. The pixel drive line 50 may be connected to an output terminal of the drive circuit 30, wherein the output terminal is configured to drive corresponding column of SPAD pixels 11. The output signal line 60 may be connected to an input terminal of the output circuit 40, wherein the input terminal is configured to receive input signal from corresponding row of SPAD pixels 11.

For driving the SPAD pixels 11 of the pixel array 10 simultaneously or sequentially by column, the drive circuit 30 may include a shift register or an address decoder. The drive circuit 30 may include a circuit that applies a quench voltage VQ to each of the SPAD pixels 11. When the drive circuit drives the SPAD pixels 11 sequentially by column, the drive circuit 30 may apply a selection signal voltage to corresponding selected column of SPAD pixels 11. A power supply voltage may be applied to the selected SPAD pixels, and the selected SPAD pixels may output a detection signal VOUT based on the selection signal voltage and the power supply voltage.

The output circuit 40 may receive the detection signal VOUT from the SPAD pixel 11 through the output signal line 60. The detection signal VOUT may be an image signal.

The control circuit 20 may include a timing generator that generates various timing signals for controlling the drive circuit 30 and the output circuit 40.

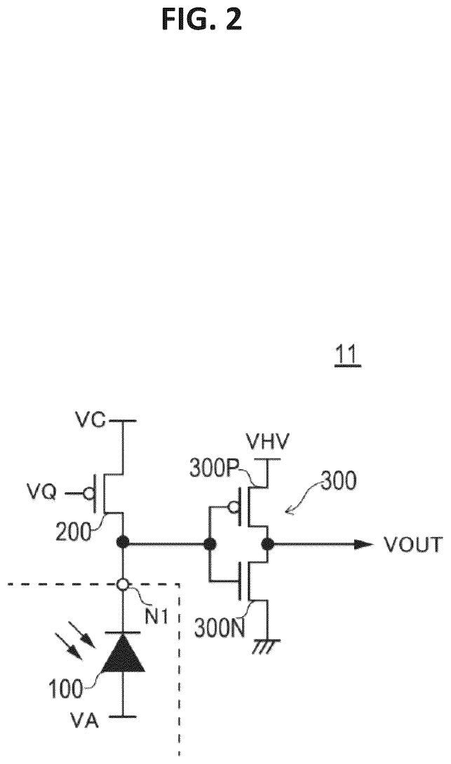

FIG. 2 is a circuit diagram illustrating an example of the schematic configuration of the SPAD pixel 11.

The SPAD pixel 11 may include a SPAD element 100, a quench resistor 200, and an inverter 300. The SPAD element 100 may be formed in a pixel chip 500, and the quench resistor 200 and the inverter 300 may be formed in a logic chip 600. The SPAD pixel 11 may be formed by bonding the pixel chip 500 with the logic chip 600. Connection points of the pixel chip 500 and the logic chip 600 are aligned and bonded to form the SPAD pixel 11. As illustrated in FIG. 2, the quench resistor 200 and the SPAD element 100 are connected at a node N1, which is one of connection points while bonding the pixel chip 500 and the logic chip 600. A dashed line in FIG. 2 indicates the boundary illustrating a portion of the pixel chip 500 and a portion of the logic chip 600 in the SPAD pixel 11.

The SPAD element 100 has two electrodes for functioning as a diode, in which one electrode is anode electrode and the other electrode is cathode electrode. Hereinafter, the anode electrode is simply referred to as an anode, and the cathode electrode is simply referred to as a cathode. The SPAD element 100 may receive incident light and generate charge based on the incident light while a reverse bias is applied between the anode and the cathode of the SPAD element 100. When the SPAD element 100 receives a photon in the revere bias where the reverse bias is slightly higher than or equal to a breakdown, the SPAD element 100 may generate an avalanche current. An anode voltage VA may be applied to the anode of the SPAD element 100, and a cathode voltage VC may be applied to the cathode of the SPAD element 100 through the quench resistor 200. For example, the anode voltage VA may be set to about −15V to about −30V. For example, the cathode voltage VC may be se to 3 V. When a reverse bias voltage is higher than or equal to a breakdown voltage of the SPAD element 100, the SPAD element 100 may operate in Geiger mode and may detect a single photon. The reverse bias voltage across the SPAD element 100 may be estimated from sum of the absolute value of the anode voltage VA and the absolute value of the cathode voltage VC. For example, the reverse bias voltage may be about 18V to about 33V when the anode voltage VA is about −15V to about −30V and the cathode voltage VC is 3 V, in which the reverse bias voltage may be slightly higher than or equal to the breakdown voltage of the SPAD element 100.

The quench resistor 200 may include a P-channel metal-oxide semiconductor (PMOS) transistor, and the gate electrode of the PMOS transistor is controlled by the quench voltage VQ supplied from the drive circuit 30. The quench resistor 200 may be turned on or turned off depending on the quench voltage VQ applied to the quench resistor 200. The quench resistor 200 may flow a current in response to a voltage drop at the node N1 of the SPAD element 100 and thus perform a recharge operation that returns the voltage of the node N1 to a voltage which is slightly higher than or equal to a breakdown voltage of the SPAD element 100.

A voltage variation at the node N1 due to a current flowing through the SPAD element 100 and the quench resistor 200 may be detected by the inverter 300. The inverter 300 may output a detection signal VOUT based on the input voltage from the node N1. The detection signal VOUT may be a digital signal while the input voltage may be an analog value.

The inverter 300 may be formed by connecting a PMOS transistor 300P and an NMOS transistor 300N in series. A power supply VHV for driving a digital circuit may be connected to the source of the PMOS transistor 300P, and a ground voltage may be connected to the source of the NMOS transistor 300N. The drain of the NMOS transistor 300N may be connected to the drain of the PMOS transistor 300P. The gate of the PMOS transistor 300P and the gate of the NMOS transistor 300N are connected to each other and become an input of the inverter 300. The drain of the PMOS transistor 300P and the drain of the NMOS transistor 300N are connected to each other, and become an output of the inverter 300. The input of the inverter 300 may be connected to the node N1 which is the connection point between the SPAD element 100 and the quench resistor 200.

Upon receiving the incident light in a reverse bias state in which the reverse bias voltage is slightly higher than or equal to a breakdown voltage of the SPAD element 100, the SPAD element flows avalanche and the voltage at the node N1 may be dropped. When the voltage of the node N1 becomes lower than the threshold voltage of the PMOS transistor 300P of the inverter 300, the PMOS transistor 300P may become conductive, and thus, the voltage of the power supply VHV may drive the detection signal VOUT to a logic high level.

When the voltage of the node N1 drops below the breakdown voltage of the SPAD element 100, the avalanche current through the SPAD element 100 may stop flowing, and the voltage of the node N1 may increase by current flow from the quench resistor 200. When the voltage of the node N1 becomes higher than the threshold voltage of the NMOS transistor 300N of the inverter 300, the NMOS transistor 300N may become conductive, and pull down the detection signal VOUT to a logic low level.

Additionally, a buffer for impedance conversion may be provided at the output of the inverter 300, and the SPAD pixel 11 may output an impedance-converted detection signal VOUT.

The detection signal VOUT may be provided to the output circuit 40. The output circuit 40 may provide the detection signal VOUT to a processor through a time-to-digital converter (TDC). The processor may perform various processes on the detection signal VOUT.

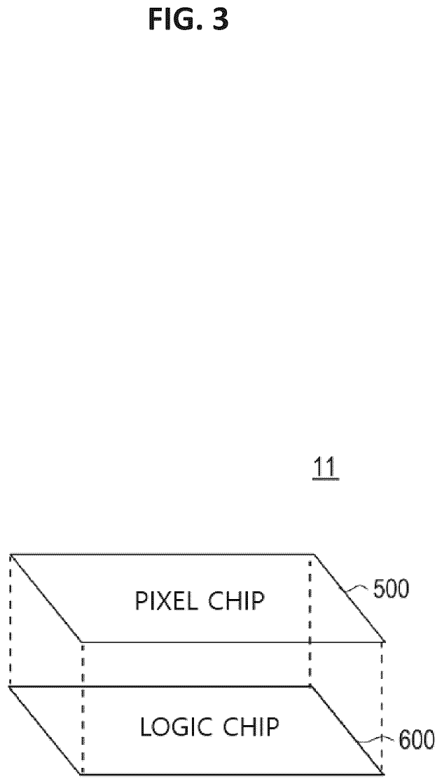

FIG. 3 is a diagram illustrating a stack structure of the pixel array 10.

The SPAD pixels 11 in the pixel array 10 may be arranged in a matrix form. The SPAD pixels 11 arranged in the matrix form may form an element array 70. The pixel array 10 may have a structure in which the pixel chip 500 and the logic chip 600 are stacked. The pixel chip 500 may include a semiconductor chip in which the SPAD elements 100 are arranged in an array. The logic chip 600 may include a semiconductor chip in which the quench resistor 200 and the inverter 300 are formed in a position aligned to the corresponding SPAD element 100. The control circuit 20, the drive circuit 30, and the output circuit 40 may be further formed in the logic chip 600. The buffer for impedance conversion of the detection signal VOUT may also be formed in the logic chip 600.

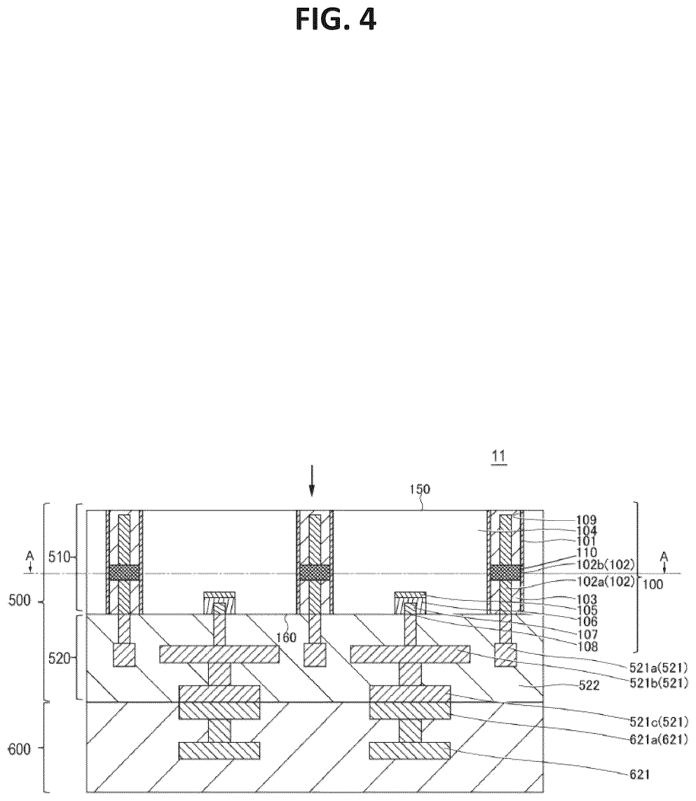

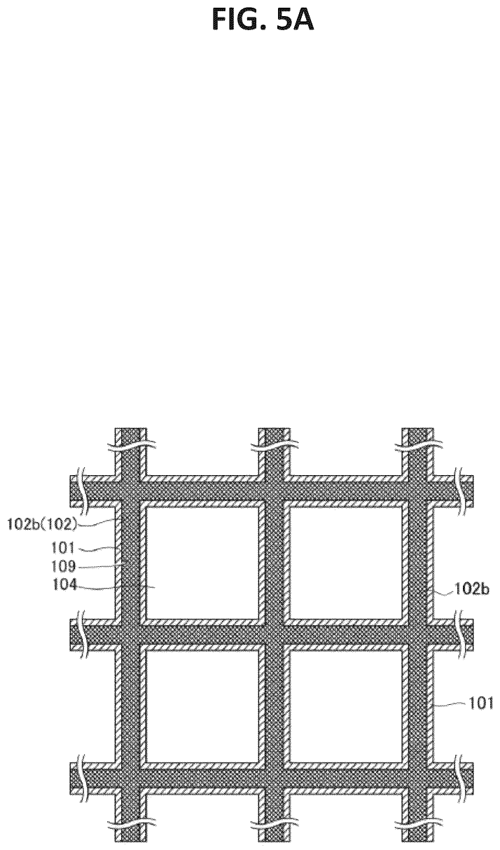

The pixel chip 500 and the logic chip 600 may be bonded to each other by planarizing respective bonding surfaces of the pixel chip 500 and the logic chip 600 and bonding the surfaces to each other with an electromagnetic force. More particularly, the pixel chip 500 and the logic chip 600 may be bonded to each other with metal pads which are formed in respective bonding surfaces of the pixel chip 500 and the logic chip 600. The metal pads may be a contact pad 521c and a contact pad 621a described below referring to FIG. 4. The metal pads may be bonded to each other by an electromagnetic force. Alternatively, the metal pads may be bonded to each other mechanically or in combination therewith.

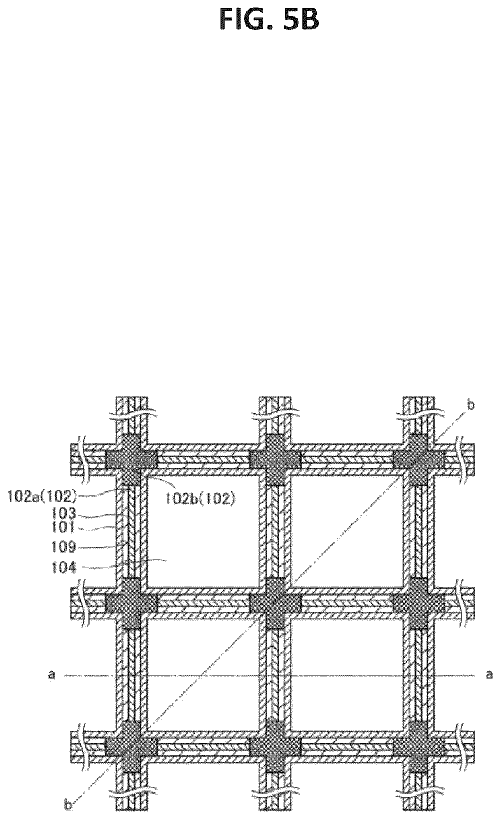

FIG. 4 is a cross-sectional view illustrating the SPAD pixel 11. FIG. 5A is a plan view of the plane A-A in FIG. 4.

Referring to FIG. 4, a surface on which light is incident may be referred to as a light entry surface 150 of the semiconductor substrate 510. Herein, the light entry surface may be referred to as a first surface 150, and the surface of the semiconductor substrate 510 which is opposite to the light entry surface may be referred to as a second surface 160. The light entry surface 150 is indicated by an arrow in FIG. 4.

A plurality of SPAD elements 100 may be formed in the semiconductor substrate 510 of the pixel chip 500. The semiconductor substrate 510 may be a silicon substrate.

Each of the SPAD elements 100 may include a trench 109 which separates each of the SPAD elements from other SPAD elements 100. The trenches 109 of the SPAD elements 100 are connected to each other in a lattice pattern when viewed from the light entry surface. The trenches 109 may penetrate the semiconductor substrate 510.

A photoelectric conversion region 104 may be surrounded by the trench 109 and may perform photoelectric conversion of incident light and generate a pair of an electron and a hole. The electron and the hole may drift depending on the bias applied across the SPAD element 100 and may cause current flow of the SPAD element 100. Herein, the electron and the hole may be referred to as “charge.” The photoelectric conversion region 104 may include a lightly doped region in which concentration of impurities for the doped region is relatively low. Alternatively, the photoelectric conversion region 104 may include an intrinsic semiconductor that is not doped with impurities.

A P-type semiconductor layer 101 formed on the sidewall of the trench 109 may include a positive-type impurity which is referred to an acceptor. The acceptor, for example, may be a boron (B). When the reverse bias voltage is applied between an anode 102 and a cathode 107 of SPAD element 100, an electric field may be established between the P-type semiconductor layer 101 and the N-type semiconductor 106. The electric field may drive the charges generated in the photoelectric conversion region 104 to a P+-type semiconductor region 105 that forms a PN junction with an N+-type semiconductor region 106. The N+-type semiconductor region 106 may be in contact with the cathode 107 of the SPAD element 100. The anode 102 may form a first electrode of the SPAD element 100 and the cathode 107 may form a second electrode of the SPAD element 100.

The P+-type semiconductor region 105 may include a relatively high concentration of acceptors. For example, a boron may be used as an acceptor. The N+-type semiconductor region 106 may include a relatively high concentration of donors. For example, phosphorus (P) or arsenic (As) may be used as a donor. The P+-type semiconductor region 105 and the N+-type semiconductor region 106 may be in contact with each other, forming a PN junction, which functions as an amplification region that generate avalanche current by accelerating charge flowing into the P+-type semiconductor region 105.

The cathode 107 may include a higher concentration of donors than the N+-type semiconductor region 106 and may be in contact with the N+-type semiconductor region 106. The cathode 107 may be ohmic-bonded to cathode wiring 521b that is a wiring pattern of a metal layer formed in a wiring layer 520. A portion in which the cathode 107 and the cathode wiring 521b are in contact with each other may be referred to as a cathode contact 108. The cathode contact 108 may form a second contact.

A first insulating film 103 may be formed in the trench 109 covering a portion of the P-type semiconductor layer 101.

The anode 102 may be formed in the trench 109. The anode 102 may include a non-contact portion 102a which is surrounded by the first insulating film 103 and is not in contact with the P-type semiconductor layer 101, and an anode end portion 102b which is in contact with the P-type semiconductor layer 101 and forms an anode contact 110. The anode end portion 102b may form an electrode of the anode 102. A portion of the anode 102 which is in contact with the P-type semiconductor layer 101 may be referred to as the anode contact 110. The non-contact portion 102a of the anode 102 may include a polysilicon. The anode end portion 102b may include P-type polysilicon. The anode contact 110 may form a first contact of the SPAD element 100.

The anode contact 110 may be closer to the light incident surface than is the cathode contact 108 and increases distance from the cathode contact 108. Accordingly, the increased distance between the anode contact 110 and the cathode contact 108 may reduce the noise generated from the strong electric field between the PN-junction and the anode 102.

FIG. 5A is a plan view of the A-A plane in FIG. 4 according to an embodiment. Referring to FIG. 5A, the anode end portion 102b may be formed in the entire region of the trench 109 including a region where trenches 109 intersect with each other. Accordingly, the anode contact 110 may be formed in the entire region along the trench 109.

Alternatively, the anode contact 110 may be formed only in the region where the trenches 109 intersect with each other in the pixel array 10. FIG. 5B is the plan view of the plane A-A in FIG. 4 according to an embodiment. Referring to FIG. 5B, the anode end portion 102b may be formed only in a region where trenches 109 intersect with each other. Accordingly, the anode contact 110 may be formed only in the region where the trenches 109 intersect with each other. By limiting the anode contact 110 to be formed in the region where trenches 109 intersect with each other, the noise generated from the strong electric field between the PN-junction and the anode 102 may be reduced. Although, an embodiment in which the anode contact 110 formed in the region where the trenches 110 intersect with each other in the pixel array 10 is described, the anode contact may be formed in other regions of the trenches 109 in the pixel array 10.

Additionally, an anti-reflective layer may be formed on the light incident surface of the semiconductor substrate 510 to prevent reflection of the incident light.

A color filter and an on-chip lens which correspond to each SPAD element 100 may be formed on the anti-reflective layer. The color filter corresponding to each SPAD element 100 may selectively transmit different wavelength component of the incident light. The different wavelength component may be a red-wavelength component, a green-wavelength component, or a blue-wavelength component. Color filters may be arranged in a Bayer pattern.

The wiring layer 520 may be formed on the opposite surface to the light incident surface of the semiconductor substrate 510. The wiring layer 520 may include a second insulating film 522 and wiring 521. Multiple layers of the wiring 521 may be stacked through the second insulating film 522. The multiple layers of the wiring 521 for the same node may be connected to each other through a via formed in the second insulating film 522. The wiring 521 may include anode wiring 521a, which provides the anode voltage VA to the SPAD element 100, and the cathode wiring 521b, which provides the cathode voltage VC to the SPAD element 100. The anode wiring 521a may be connected to the anode 102. The cathode wiring 521b may be connected to the cathode 107. The wiring 521 may include a connection pad 521c. The connection pad 521c may be exposed on a surface of the wiring layer 520. The surface of the wiring layer 520 may be the bottom surface of the wring layer 520 as described referring to FIG. 4.

The connection pad 521c may be metallically bonded to a connection pad 621a exposed on a surface of the logic chip 600. The surface of the logic chip 600 may be a top surface of the logic chip 600 as described referring to FIG. 4. Accordingly, the pixel chip 500 may be bonded to the logic chip 600 through the connection pad 621a.

The logic chip 600 may include a substrate and a wiring layer. The substrate may include a device, in which a logic circuit including the quench resistor 200 and the inverter 300 may be formed. In addition, wiring for the logic circuit to connect the quench resistor 200 with the inverter 300, or wiring 621 for connecting the logic chip 600 to wiring layer 520 through the connection pad 621a may be formed in the wiring layer.

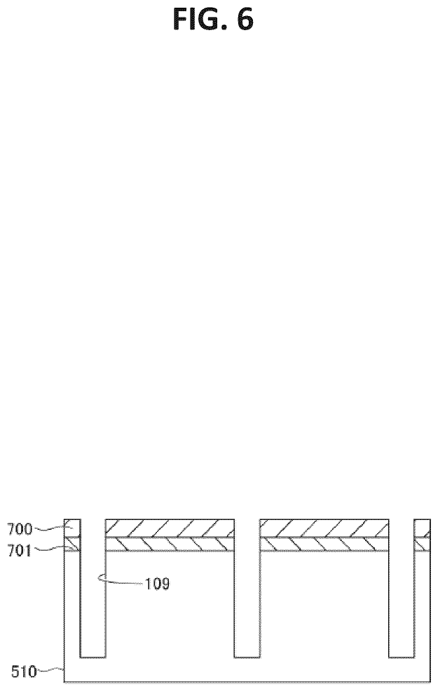

FIGS. 6 to 16 are diagrams illustrating a method of manufacturing the image sensor 1. More particularly, FIGS. 6 to 16 may illustrate a method of manufacturing the SPAD pixel 11 of the image sensor 1 shown in FIG. 5A.

Referring to FIG. 6, layers of hard-mask materials 700 and 701 may be formed on the opposite surface to the light incident surface of the semiconductor substrate 510. Through patterning the layers of hard-mask materials 700 and 701 corresponding to the trench 109, a hard-mask may be formed on the opposite surface to the light incident surface of the semiconductor substrate 510. An etching process such as reactive ion etching may performed on the opposite surface to the light incident surface of the semiconductor substrate 501 using the hard-mask to form the trench 109. During the reactive ion etching, the hard-mask which has an opening corresponding to the pattern of the trench 109 may be used as an etch mask.

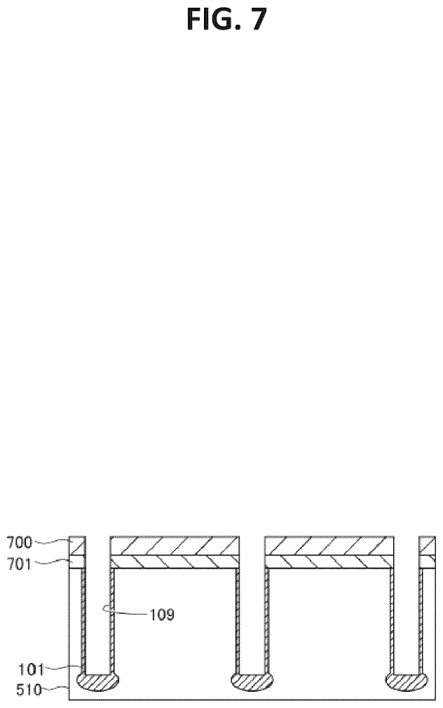

Referring to FIG. 7, the P-type semiconductor layer 101 may be formed on the sidewall of the trench 109 by injecting an acceptor such as boron and activating the acceptor through heat treatment. The acceptor may be injected through plasma doping process. Alternatively, the P-type semiconductor layer 101 may be formed by depositing a material including an acceptor such as boron inside the trench 109. After solidifying the material, heat treatment may be performed to diffuse the boron into the sidewall of the trench 109. The material may be a glass material.

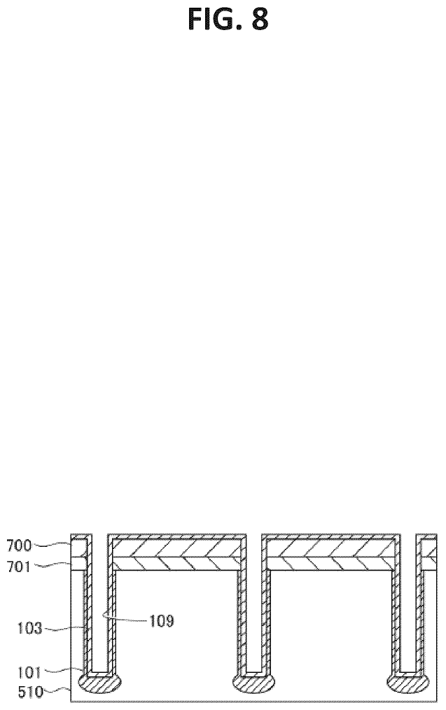

Referring to FIG. 8, the first insulating film 103 may be formed in the trench 109 to cover the P-type semiconductor layer 101. For example, the first insulating film 103 may be formed by depositing SiO₂ on the P-type semiconductor layer 101 through chemical vapor deposition (CVD).

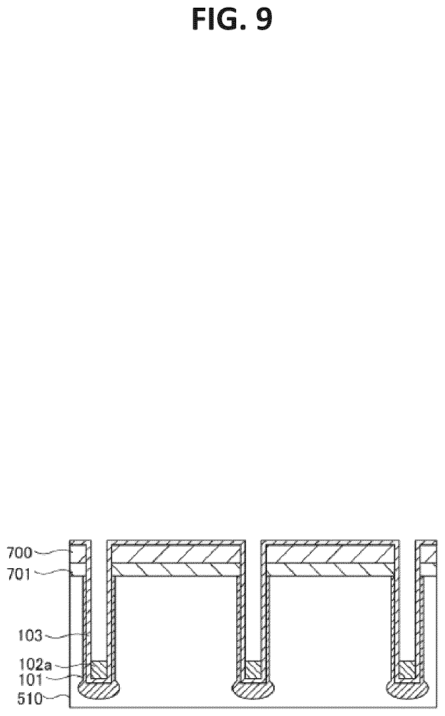

Referring to FIG. 9, the non-contact portion 102a of the anode 102, which is in contact with the first insulating film 103, may be formed in a portion of the trench 109 in which the first insulating film 103 has been formed. The non-contact portion 102a of the anode 102 may be formed by depositing polysilicon in the trench 109 through CVD and etching back upper portion of the deposited polysilicon.

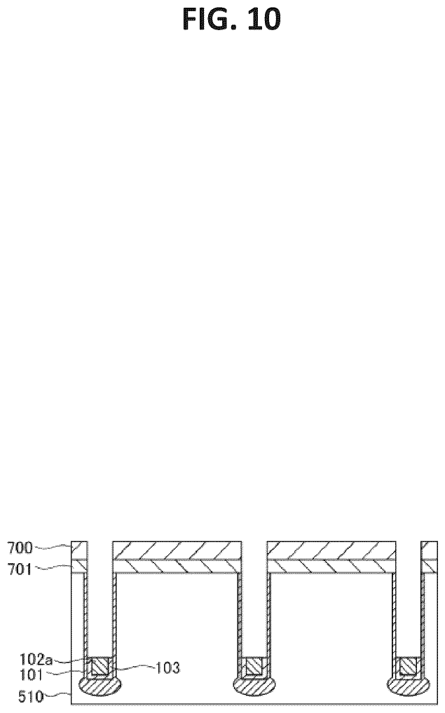

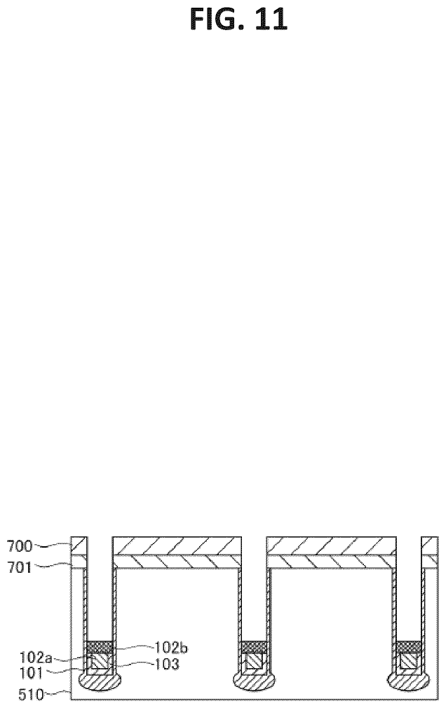

Referring to FIG. 10, a portion of the first insulating film 103 that is not in contact with the non-contact portion 102a of the anode 102 may be removed by isotropic etching such as wet etching.

Referring to FIG. 11, the anode end portion 102b may be formed on and in contact with the non-contact portion 102a of the anode 102. Because the anode end portion 102b may be formed in the portion of the trench 109 in which the first insulating film 103 is removed and the P-type semiconductor layer 101 is exposed, the anode end portion 102b may be in contact with the P-type semiconductor layer 101. The anode end portion 102b may be formed by depositing polysilicon doped with an acceptor such as boron in the trench 109 through CVD and then removing upper portion of the deposited polysilicon through etch back process.

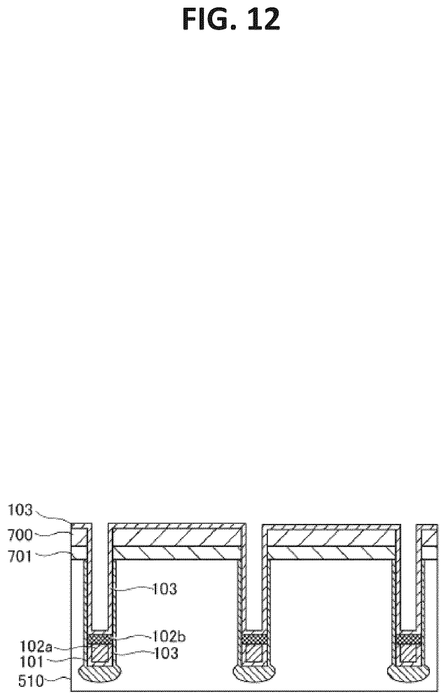

Referring to FIG. 12, the first insulating film 103 covering the P-type semiconductor layer 101 and the anode end portion 102b may be formed in the trench 109. The first insulating film 103 may be formed by depositing SiO₂ on the P-type semiconductor layer 101 and the anode end portion 102b through CVD.

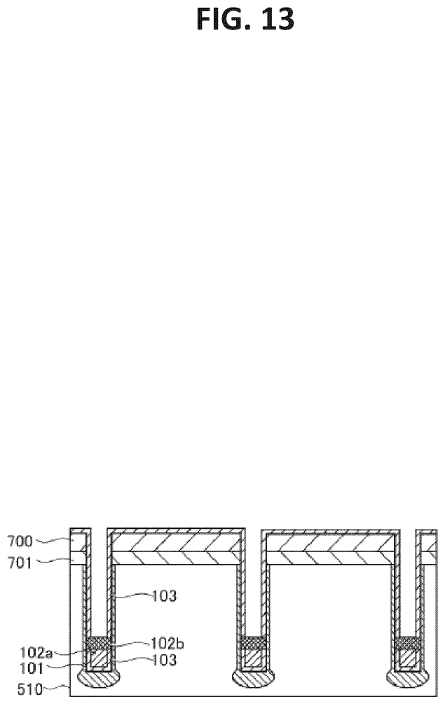

Referring to FIG. 13, the bottom portion of the first insulating film 103 may be removed by etch back process, thereby exposing the anode end portion 102b.

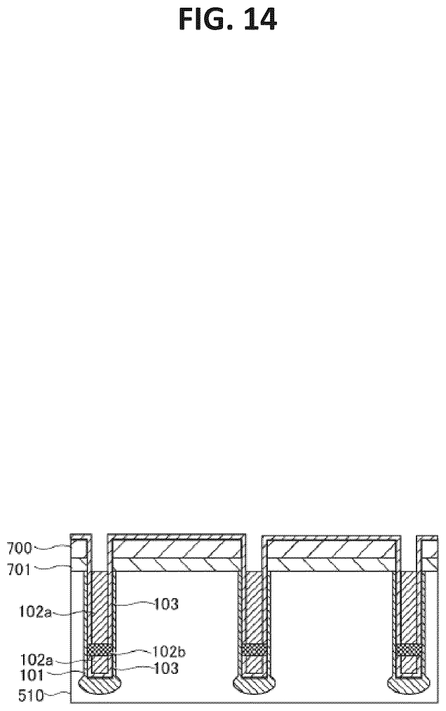

Referring to FIG. 14, the non-contact portion 102a of the anode 102 may be formed in the trench 109 to be in contact with the first insulating film 103 and the anode end portion 102b. For example, the non-contact portion 102a of the anode 102 may be formed by depositing polysilicon in the trench 109 through CVD and removing upper portion of the deposited polysilicon through etch back process.

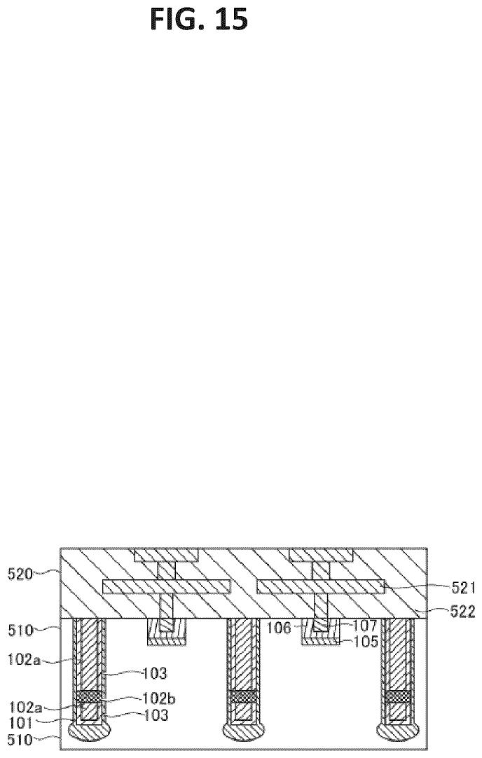

Referring to FIG. 15, the P+-type semiconductor region 105, the N+-type semiconductor region 106, and the cathode 107 may be formed in the photoelectric conversion region 104 surrounded by the trench 109. The P+-type semiconductor region 105, the N+-type semiconductor region 106, and the cathode 107 may be formed by injecting impurities such as donors and acceptors into the corresponding regions. Thereafter, the wiring layer 520 may be formed on the opposite surface to the light incident surface of the semiconductor substrate 510. The wiring layer 520 may include the second insulating film 522 and the wiring patterns 521.

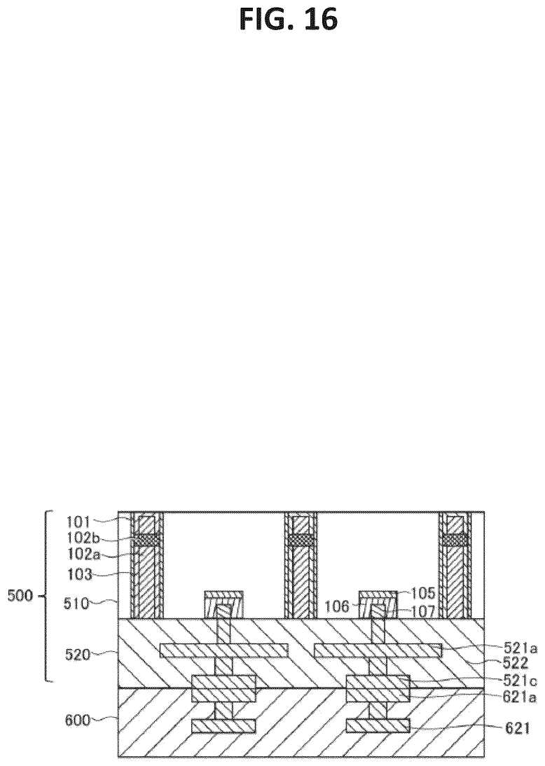

Referring to FIG. 16, the pixel chip 500 is bonded to the logic chip 600. Thereafter, the semiconductor substrate 510 may be thinned by grinding the light incident surface of the semiconductor substrate 510 until the first insulating film 103 is exposed. An anti-reflective layer may be formed on the light incident surface of the semiconductor substrate 510.

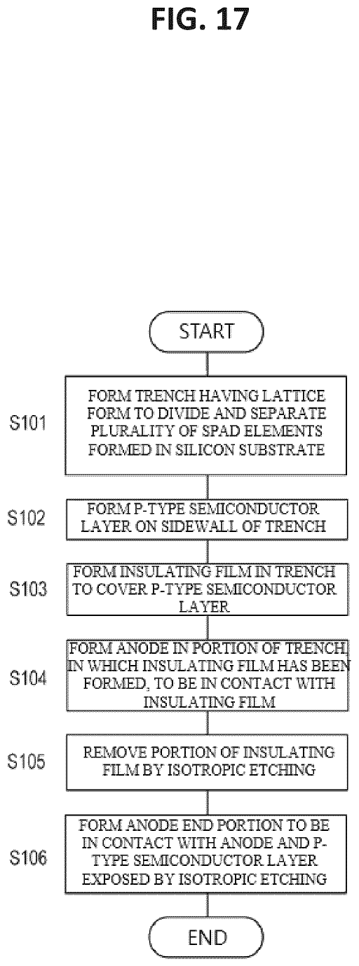

FIG. 17 is a flowchart illustrating a process for manufacturing the image sensor 11. Each step of the process is illustrated in FIGS. 6 to 11.

In the step S101, the trench 109 having a lattice pattern may be formed in a silicon substrate to divide and separate a plurality of SPAD elements 100.

In the step S102, the P-type semiconductor layer 101 may be formed on the sidewall of the trench 109.

In the step S103, the first insulating film 103 may be formed in the trench 109 for covering a portion of the P-type semiconductor layer 101.

In the step S104, the non-contact portion 102a of the anode 102 may be formed in a portion of the trench 109, in which the non-contact portion 102a of the anode 102 is surrounded by the first insulating film 103 and is not in contact with the P-type semiconductor layer 101.

In the step S105, a portion of the first insulating film 103 may be removed by isotropic etching such as wet etching.

In the step S106, the anode end portion 102b may be formed on and in contact with the non-contact portion 102a of the anode 102. Because the anode end portion 102b may be formed in the portion of the trench 109 in which the first insulating film 103 is removed and the P-type semiconductor layer 101 is exposed, the anode end portion 102b may be in contact with the P-type semiconductor layer 101.

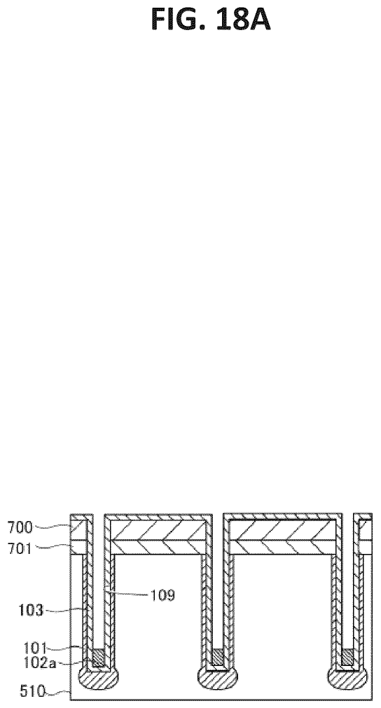

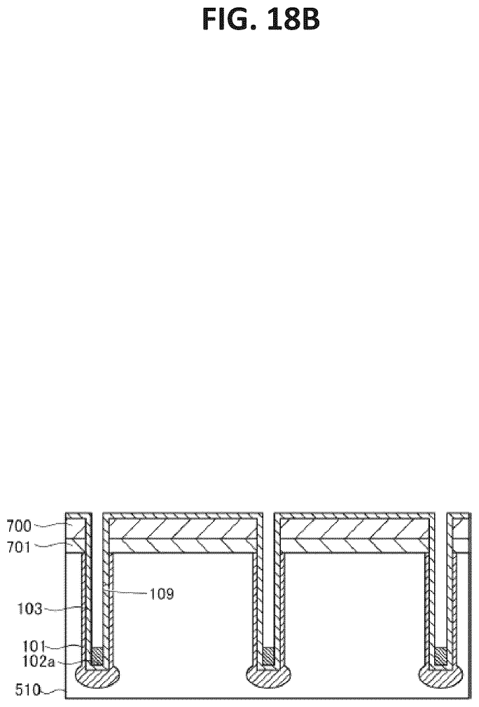

FIGS. 18A to 22B are diagrams for illustrating a process for manufacturing the image sensor 1 including the SPAD pixel 11 of FIG. 5B. Each step of the process is described referring to 18A to 22B, in which FIGS. 18A, 19A, 20A, 21A, and 22A are cross-sectional views of the plane a-a in FIG. 5B, and FIGS. 18B, 19B, 20B, 21B, and 22B are cross-sectional views of the plane b-b in FIG. 5B.

The processes illustrated in FIGS. 6 to 8 may also be applied for manufacturing the image sensor of FIG. 5B.

Referring to FIGS. 18A and 18B, the non-contact portion 102a of the anode 102 may be formed in a portion of the trench 109, in which the non-contact portion 102a of the anode 102 is surrounded by the first insulating film 103 and is not contact with the P-type semiconductor layer 101. The non-contact portion 102a of the anode 102 may be formed in the trench 109 by depositing polysilicon through CVD and removing upper portion of the deposited polysilicon through etch back process.

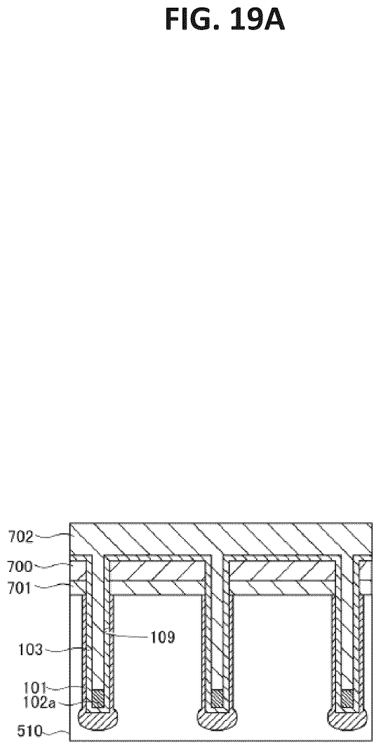

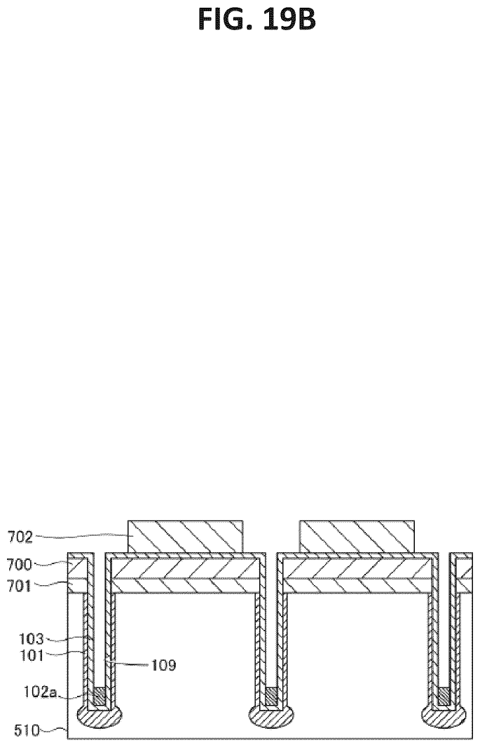

Referring to FIGS. 19A and 19B, a resist film 702 may be formed to cover the region of the trench 109 except the intersection region of the trench 109. Accordingly, as shown in FIG. 19A, the trench 109 other than the intersection region is filled with the resist film 702, while the intersection region of the trench 109 is not filled with the resist film 702 as shown in FIG. 19B.

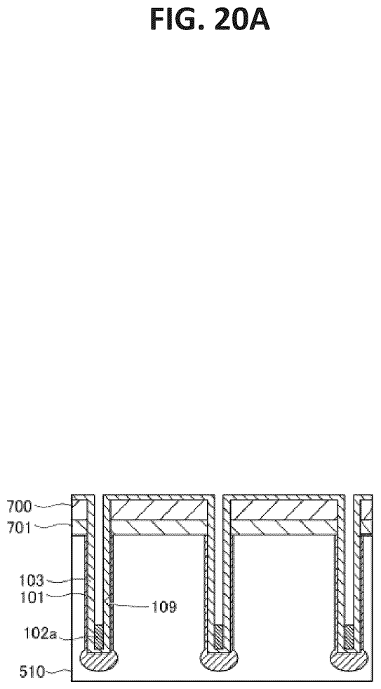

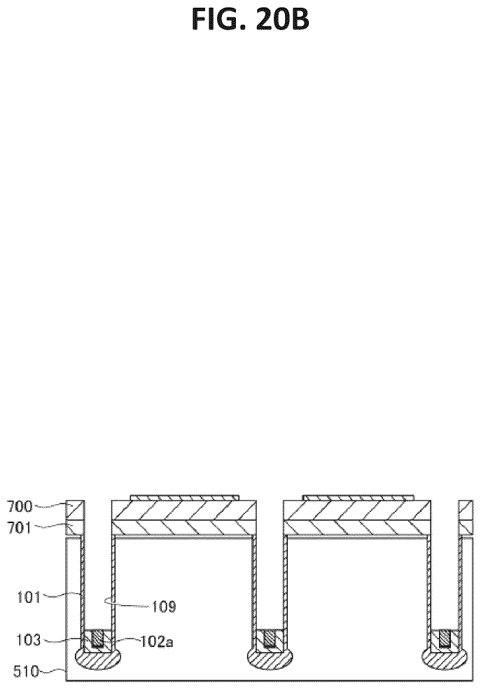

Referring to FIG. 20B, a portion of the first insulating film 103 that is not in contact with the non-contact portion 102a of the anode 102 may be removed by isotropic etching such as wet etching. Referring to FIG. 20A, the first insulating film 103 in the trench 109 other than the intersection region of the trench 109 may not be removed by the isotropic etching because the resist film 702 covers the region of the trench 109 except the intersection region of the trench 109.

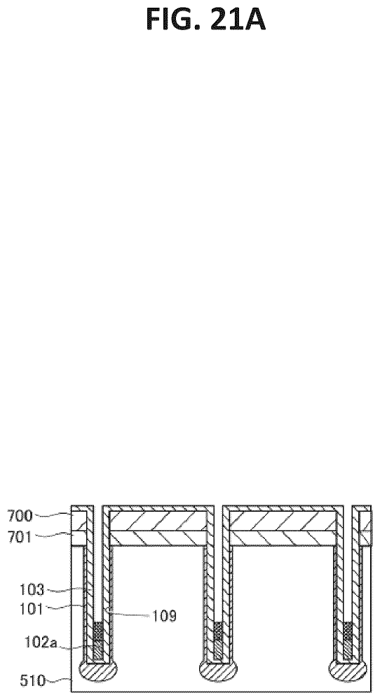

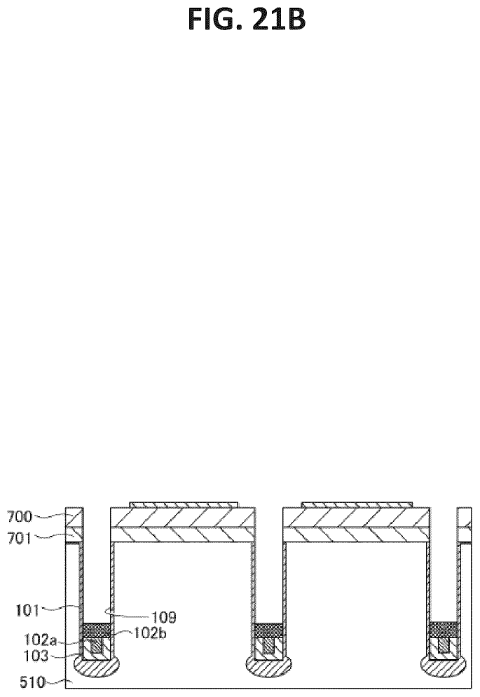

Referring to FIG. 21B, the anode end portion 102b may be formed on and in contact with the non-contact portion 102a of the anode 102. Because the anode end portion 102b may be formed in the portion of the trench 109 in which the first insulating film 103 is removed and the P-type semiconductor layer 101 is exposed, the anode end portion 102b may be in contact with the P-type semiconductor layer. The anode end portion 102b may be formed by depositing polysilicon doped with an acceptor such as boron in the trench 109. The anode end portion 102b may be formed by depositing polysilicon in the trench through CVD, and removing upper portion of the deposited polysilicon through etch back process. Referring to FIG. 21A, a layer including the same material as the anode end portion 102b may be formed in the region of the trench 109 except the intersection region of the trench 109 to be in contact with the anode 102 and the first insulating film 103.

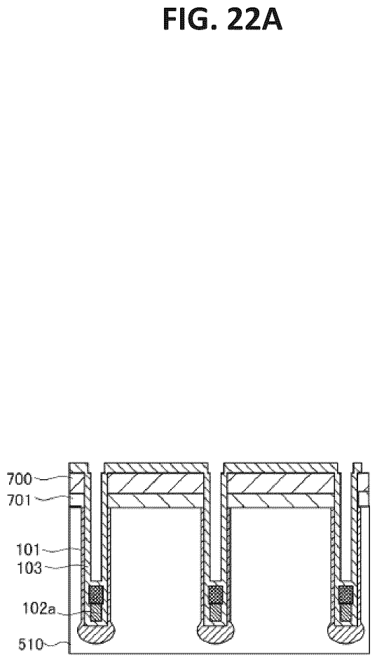

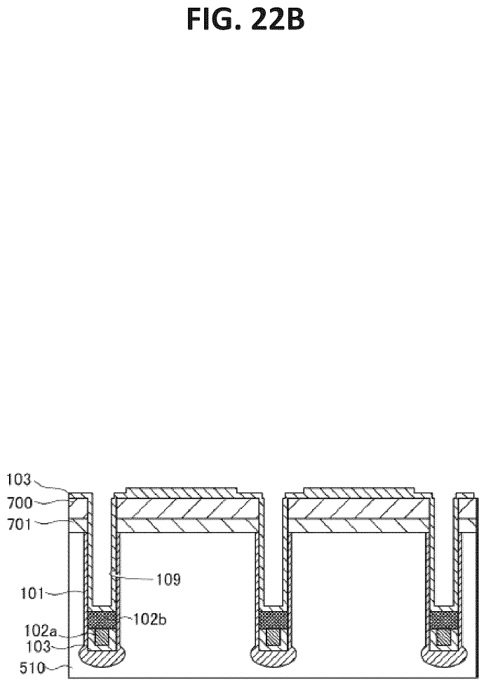

Referring to FIG. 22B, the first insulating film 103 may be formed in the trench 109 to cover the P-type semiconductor layer 101 and the anode end portion 102b. The first insulating film 103 may be formed by depositing SiO₂ on the P-type semiconductor layer 101 and the anode end portion 102b through CVD. Referring to FIG. 22A, the first insulating film 103 may also be formed in the region of the trench 109 except the intersection region of the trench 109. The layer including the same material as the anode end portion 102b may be formed in the region of the trench 109 other than the intersection region of the trench 109 to be in contact with the anode 102 and the first insulating film 103, and is not in contact with the P-type semiconductor layer 101. Thereafter, the processes illustrated in FIGS. 13 to 16 may be performed in same manner.

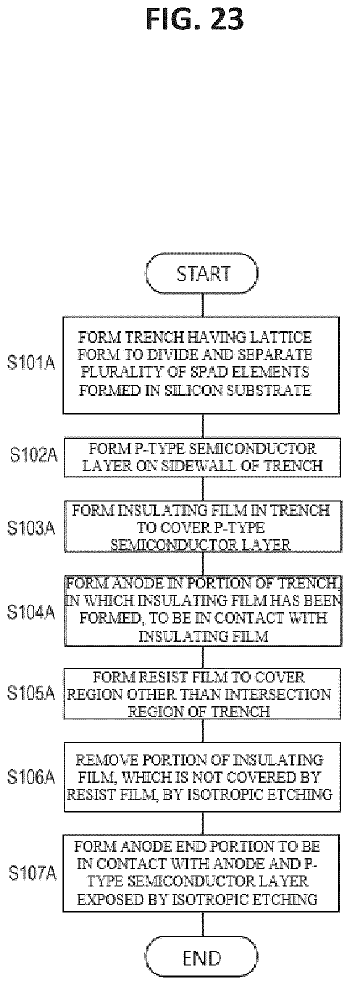

FIG. 23 is a flowchart illustrating a process for manufacturing the image sensor 1. Each step of the process is illustrated in FIGS. 18A to 22B.

In the step S101A, the trench 109 having a lattice pattern may be formed in a silicon substrate to divide and separate a plurality of SPAD elements 100.

In the step S102A, the P-type semiconductor layer 101 may be formed on the sidewall of the trench 109.

In the step S103A, the first insulating film 103 may be formed in the trench 109 to cover a portion of the P-type semiconductor layer 101.

In the step S104A, the non-contact portion 102a of the anode 102 may be formed in a portion of the trench 109, in which the non-contact portion 102a of the anode 102 is surrounded by the first insulating film 103 and is not in contact with the P-type semiconductor layer 101.

In the step S105A, a resist film 702 may be formed to cover the region except the intersection region of the trench 109.

In the step S106A, a portion of the first insulating film 103, which is in the trench 109 and is not covered by the resist film 702, may be removed by isotropic etching such as wet etching.

In the step S107A, the anode end portion 102b may be formed on and in contact with the non-contact portion 102a of the anode 102. Because the anode end portion 102b may be formed in the portion of the trench 109 in which the first insulating film 103 is removed and the P-type semiconductor layer 101 is exposed, the anode end portion 102b may be in contact with the P-type semiconductor layer 101. Consequently, the anode end portion 102b may be formed only in the intersection region of the trench 109.

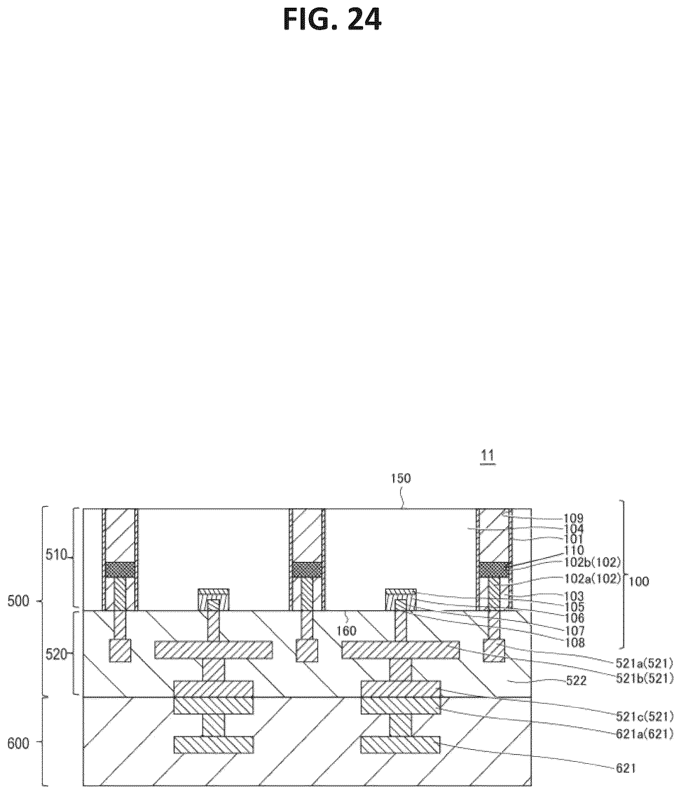

FIG. 24 is a cross-sectional view illustrating a structure of the SPAD pixel 11.

The non-contact portion 102a of the anode 102 may not be formed at the side of the light incident surface of the semiconductor substrate 510.

The anode end portion 102b may be formed not to be in contact with the light incident surface of the semiconductor substrate 510. Alternatively, the anode end portion 102b may be formed to be in contact with the light incident surface of the semiconductor substrate 510.

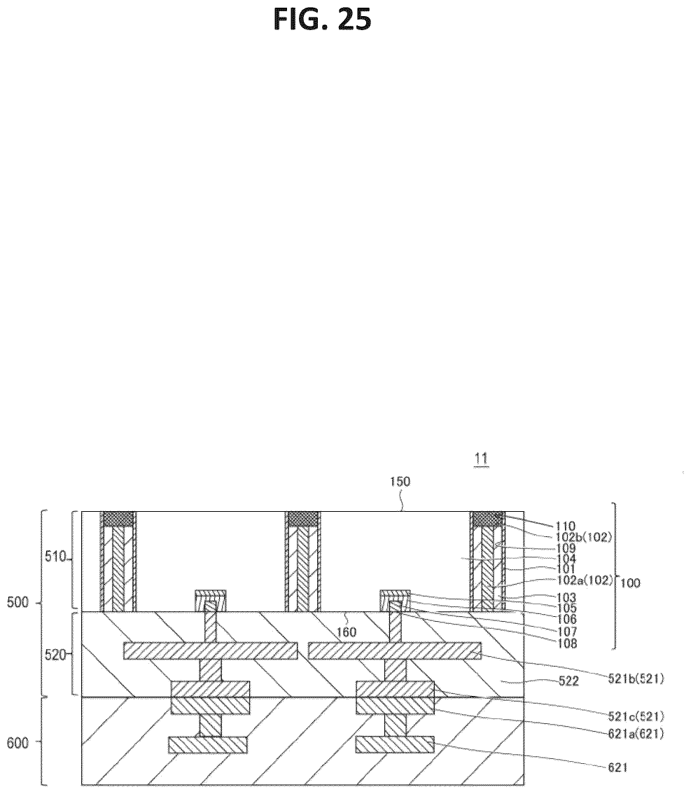

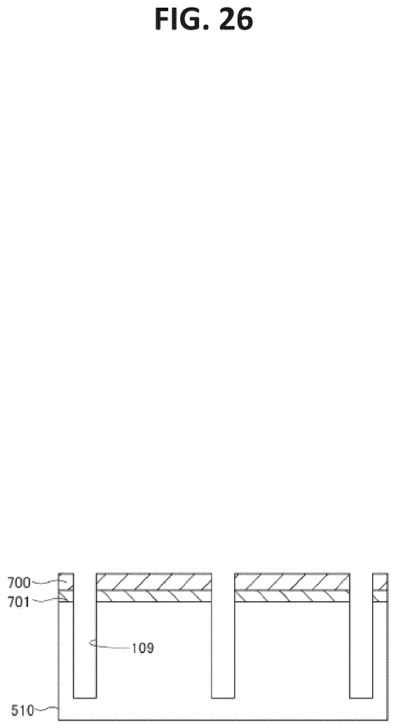

FIG. 25 is a cross-sectional view illustrating a structure of the SPAD pixel 11. FIGS. 26 to 31 are diagrams illustrating a method of manufacturing the image sensor 1.

Referring to FIG. 25, the anode end portion 102b may be formed close to the light incident surface of the semiconductor substrate 510. Accordingly, the anode contact 110 may be formed in a position close to the light incident surface of the semiconductor substrate 510.

Referring back to FIG. 5A, the anode 102 of each of a plurality of SPAD elements 100, which are arranged in a matrix form to form the element array 70, may be arranged in a lattice pattern along with the trench 109. The anode 102 may be connected to power supply wiring 51, which provides the anode voltage VA from outside the pixel array 10 as shown in FIG. 25. Because the anode voltage VA may be applied to each anode 102 of the SPAD elements 100 from outside the pixel array 10, it may not be necessary to form the anode wiring 521a of the wiring layer 520.

Referring to FIG. 25, the anode wiring 521a may not be formed in the wiring layer 520, and the cathode wiring 521b may extend to a region in which the trench 109 is formed. When the semiconductor substrate 510 is viewed from the side of the light incident surface, an interstitial space of the trench 109 having a lattice pattern may be covered by the cathode wiring 521b. Because the cathode wiring 521b may function as a reflector of the incident light, photon detection efficiency (PDE) may be increased.

Referring to FIG. 26, layers of hard-mask materials 700 and 701 may be formed on the opposite surface to the light incident surface of the semiconductor substrate 510. Through patterning the layers of hard-mask materials 700 and 701 corresponding to the trench 109, a hard-mask may be formed on the opposite surface to the light incident surface of the semiconductor substrate 510. An etching process such as reactive ion etching may performed on the opposite surface to the light incident surface of the semiconductor substrate 501 using the hard-mask to form the trench 109. During the reactive ion etching, the hard-mask which has an opening corresponding to the pattern of the trench 109 may be used as an etch mask.

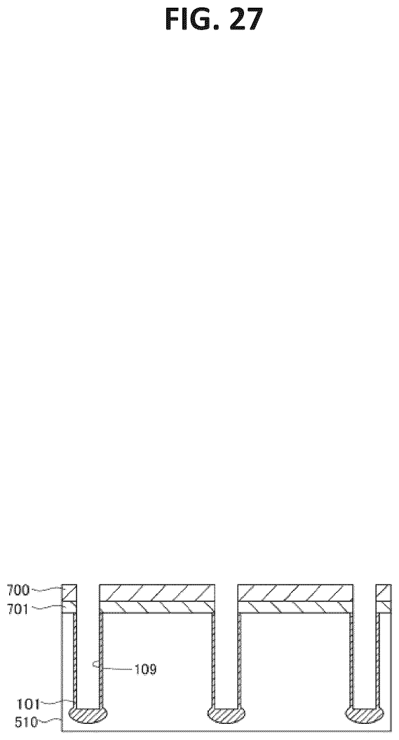

Referring to FIG. 27, the P-type semiconductor layer 101 may be formed on the sidewall of the trench 109 by injecting an acceptor such as boron, and activating the acceptors through heat treatment. The acceptor may be injected through plasma doping process. Alternatively, the P-type semiconductor layer 101 may be formed by depositing a material including an acceptor such as boron inside the trench 109. After solidifying the material, heat treatment may be performed to diffuse the boron into the sidewall of the trench 109. The material may be a glass material.

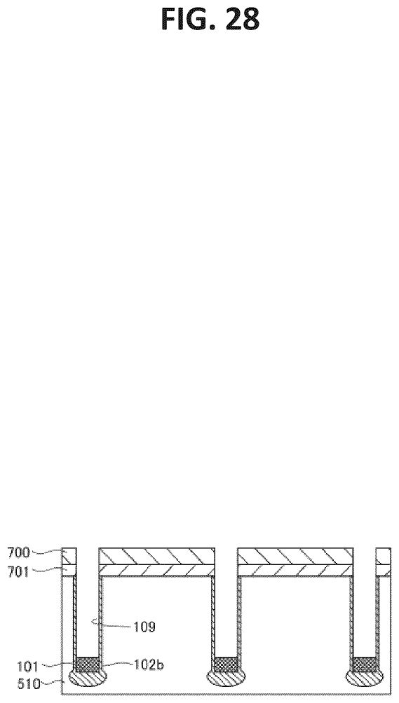

Referring to FIG. 28, the anode end portion 102b may be formed on and in contact with the non-contact portion 102a of the anode 102. Because the anode end portion 102b may be formed in the portion of the trench 109 in which the first insulating film 103 is removed and the P-type semiconductor layer 101 is exposed, the anode end portion 102b may be in contact with the P-type semiconductor layer 101. The anode end portion 102b may be formed by depositing polysilicon doped with an acceptor such as boron, and by removing upper portion of the deposited polysilicon through etch back process.

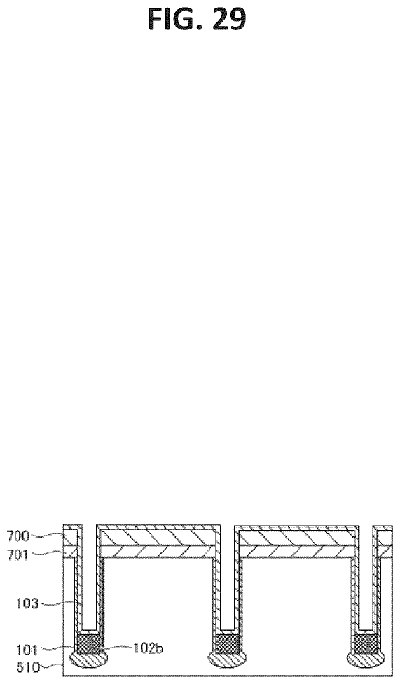

Referring to FIG. 29, the first insulating film 103 may be formed in the trench 109 to cover the P-type semiconductor layer 101 and the anode end portion 102b. The first insulating film 103 may be formed by depositing SiO₂ on the P-type semiconductor layer 101 through CVD.

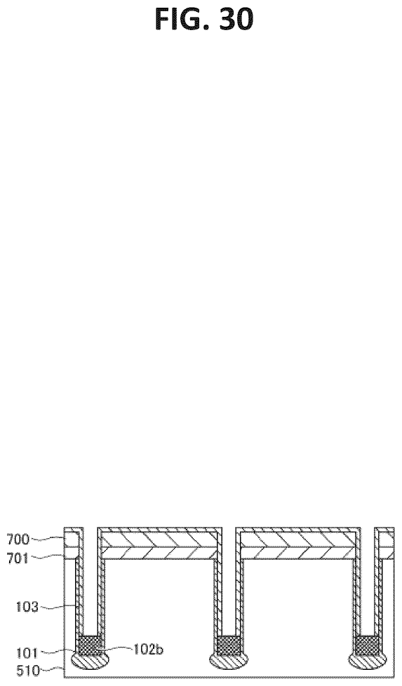

Referring to FIG. 30, the anode end portion 102b may be exposed by removing a portion of the first insulating film 103 by etch back process.

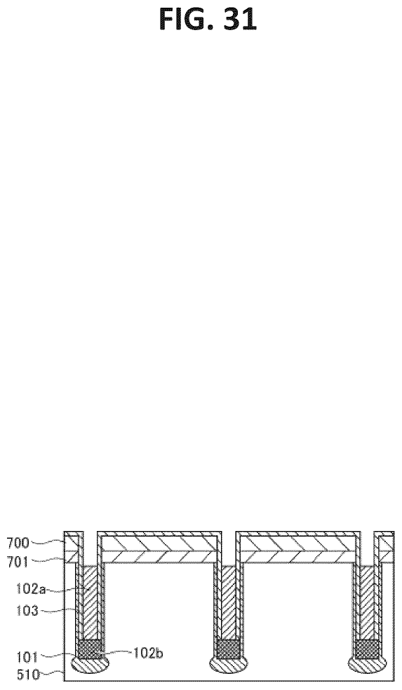

Referring to FIG. 31, the non-contact portion 102a of the anode 102 may be formed in the trench 109 to be in contact with the anode end portion 102b that has been exposed through the etch back process. The non-contact portion 102a of the anode 102 may be formed by depositing polysilicon in the trench 109 through CVD and removing upper portion of the polysilicon through etch back process. The subsequent process may be the same as described with reference to FIGS. 15 and 16.

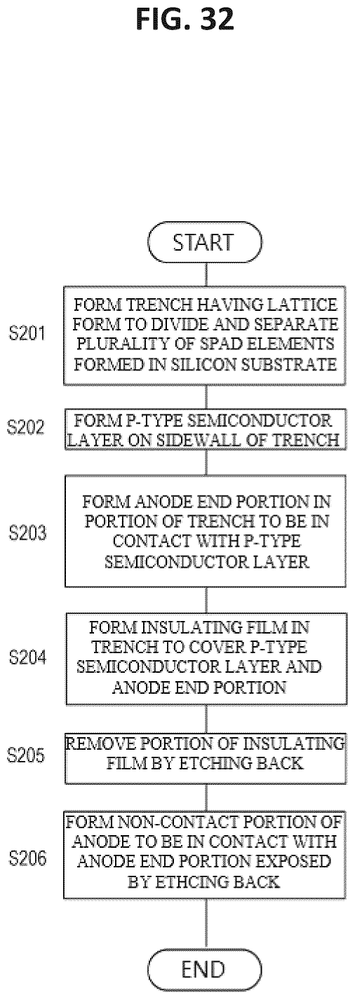

FIG. 32 is a flowchart illustrating a process for manufacturing the image sensor 1. Each step of the process is illustrated in FIGS. 26 to 31.

In the step S201, the trench 109 having a lattice pattern may be formed in a silicon substrate to divide and separate a plurality of SPAD elements 100.

In the step S202, the P-type semiconductor layer 101 may be formed on the sidewall of the trench 109.

In the step S203, the anode end portion 102b may be formed in a portion of the trench 109 to be in contact with the P-type semiconductor layer 101. Accordingly, an anode contact of each of the SPAD elements 100 may be formed.

In the step S204, the first insulating film 103 may be formed in the trench 109 to cover a portion of the P-type semiconductor layer 101 and the anode end portion 102b.

In the step S205, a portion of the first insulating film 103 may be removed by etch back process.

In the step S206, the non-contact portion 102a of the anode 102 may be formed to be in contact with the anode end portion 102b, which has been exposed through the etch back process on the first insulating film 103.

The non-contact portion 102a of the anode 102 includes polysilicon. Alternatively, the non-contact portion 102a of the anode 102 may include metal, in which a light transmittance of the metal is lower than that of the polysilicon.

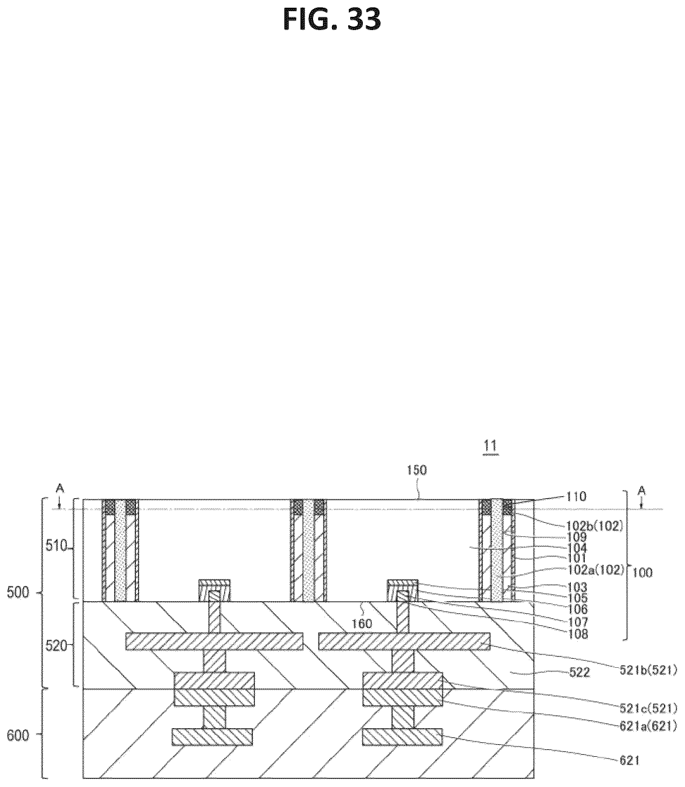

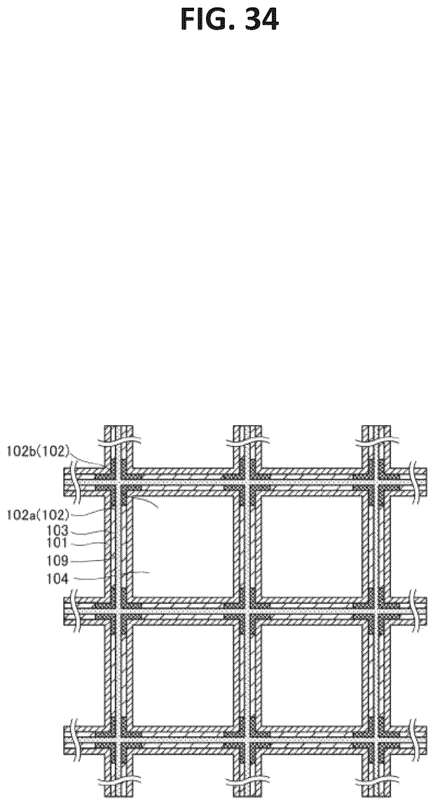

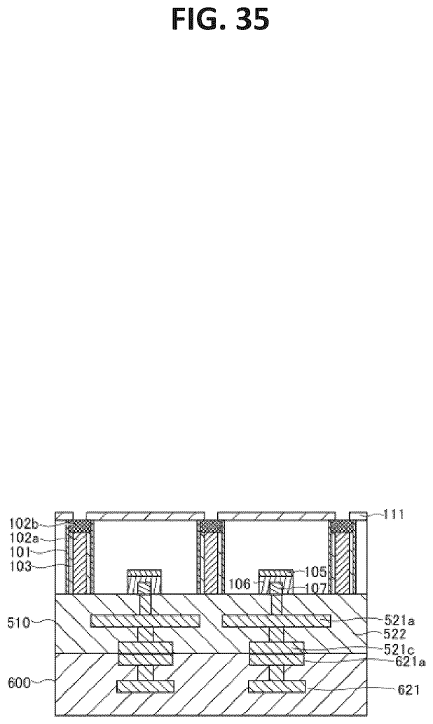

FIG. 33 is a cross-sectional view illustrating the structure of the SPAD pixel 11. FIG. 34 is a plan view of the plane A-A in FIG. 33. FIGS. 35 to 38 are diagrams illustrating a process for manufacturing the image sensor 1.

Referring to FIGS. 33 and 34, the non-contact portion 102a of the anode 102 may include metal, in which a light transmittance of the metal is lower than that of the polysilicon. The metal may be referred to as “low light transmittance metal,” and may include tungsten (W) and aluminum (Al). Because of the low light transmittance metal, the SPAD element 100 may be better separated from adjacent SPAD elements. Because the anode end portion 102b may be in contact with the light incident surface of the semiconductor substrate 510, the anode contact 110 may be close to the light incident surface of the semiconductor substrate 510.

The anode 102 of each of a plurality of SPAD elements 100, which are arranged in a matrix form to form the element array 70, may be arranged in a lattice pattern along with the trench 109. The anode 102 may be connected to power supply wiring that provides the anode voltage VA from outside the element array 70. Because the anode voltage VA may be provided to the anode 102 of each of the SPAD elements 100 from outside the element array 70, it may not be necessary to form the anode wiring 521a in the wiring layer 520.

As shown in FIG. 33, the anode wiring 521a may not be formed in the wiring layer 520, and the cathode wiring 521b may extend to a region in which the trench 109 is formed. When the semiconductor substrate 510 is viewed from the light incident surface, an interstitial space of the trench 109 having a lattice pattern may be covered by the cathode wiring 521b. Because the cathode wiring 521b may function as a reflector of incident light, a photon detection efficiency (PDE) may be increased.

According to an embodiment, after the non-contact portion 102a of the anode 102 is formed as described with reference to FIGS. 26 to 31, the P+-type semiconductor region 105, the N+-type semiconductor region 106, and the cathode 107 may be formed by using the process described with reference to FIGS. 15 and 16. The wiring layer 520 may be formed by forming the second insulating film 522 and the wiring 521 on the opposite surface to the light incident surface of the semiconductor substrate 510. The pixel chip 500 may be bonded to the logic chip 600. Thereafter at least the non-contact portion 102a of the anode 102, which is formed of polysilicon in the trench 109, may be replaced with low light transmittance metal. Accordingly, the non-contact portion 102a of the anode 102 may be formed to include the low light transmittance metal.

Referring to FIG. 35, a portion of the anti-reflective layer 111, which corresponds to the trench 109, may be partially removed through etching using a resist film as a mask. An opening a portion of the trench 109 at the side of the light incident surface of the semiconductor substrate 510 may be formed. The etching process may be a reactive ion etching.

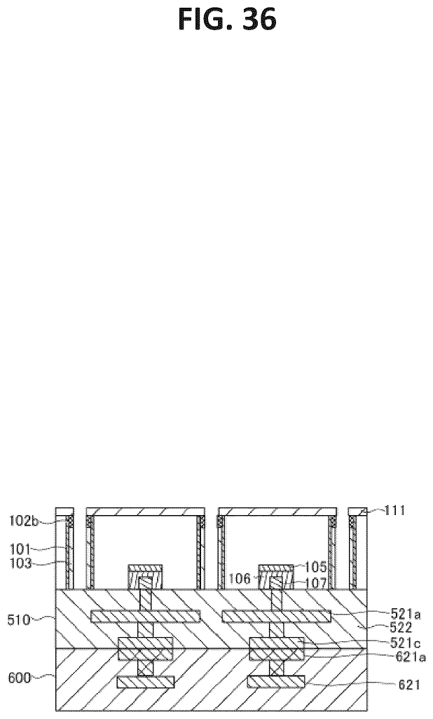

Referring to FIG. 36, upper portion of the anode 102 may be removed by etching until a portion of the anode end portion 102b which is in contact with the P-type semiconductor layer 101 is exposed. The non-contact portion 102a and the anode end portion 102b of the anode 102 may be etched by reactive ion etching. By adjusting the selectivity of reactive ion etching, appropriate portion of the anode 102 may be removed while leaving a portion of the anode end portion 102b which is in contact with the P-type semiconductor layer 101.

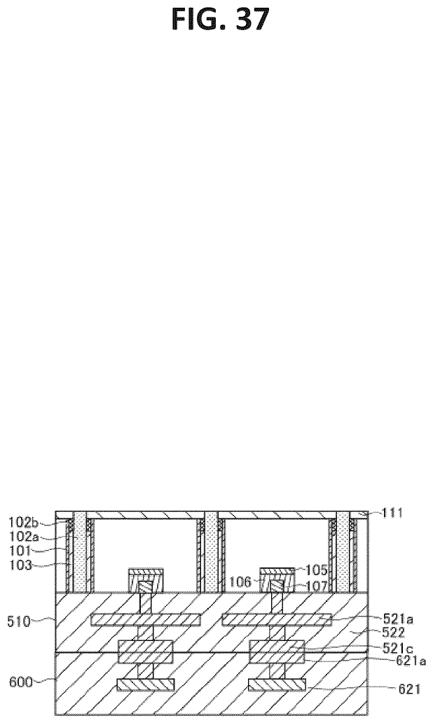

Referring to FIG. 37, a space corresponding to the removed portions of the non-contact portion 102a and the anode end portion 102b of the anode 102 by the etching may be filled with low light transmittance metal. The filling of the low light transmittance metal may be performed by CVD or sputtering. Thereafter, the low light transmittance metal may be planarized by chemical mechanical polishing (CMP) process.

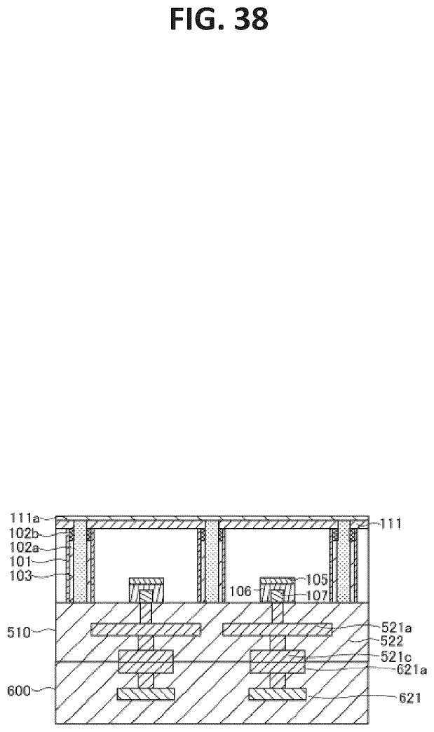

Referring to FIG. 38, an anti-reflective layer 111a may be formed to cover the planarized low light transmittance metal.

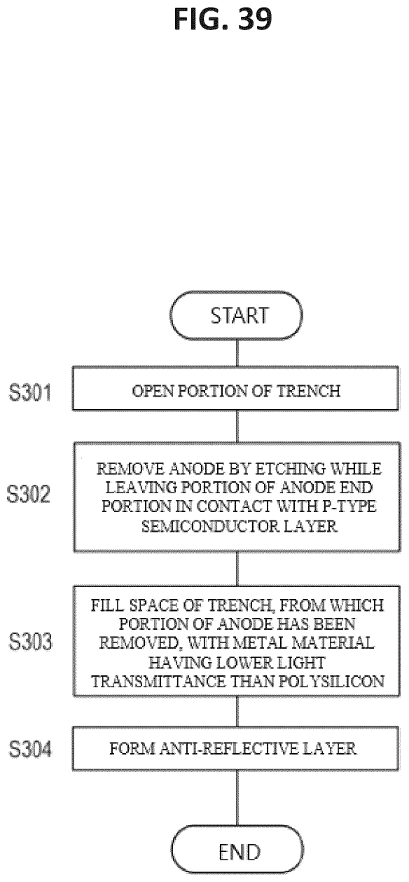

FIG. 39 is a flowchart illustrating a process for manufacturing the image sensor 1. Each step of the process is illustrated in FIGS. 35 to 38.

In the step S301, a portion of the trench 109 at the side of the light incident surface may be opened by removing a portion of the anti-reflective layer which corresponds to the trench 109.

In the step S302, the anode 102 may be removed by etching while leaving a portion of the anode end portion 102b, which is in contact with the P-type semiconductor layer 101.

In the step S303, a space corresponding to the portion of the anode 102 removed by the etching in the trench 100 may be filled with low light transmittance metal.

In the step S304, the anti-reflective layer may be formed on the semiconductor substrate 510 to cover the low light transmittance metal filling the trench 109.

The width of the trench 109 is substantially constant from the light incident surface of the semiconductor substrate 510 toward the opposite surface to the light incident surface of the semiconductor substrate 510. Accordingly, the thickness of the first insulating film 103 surrounding the anode 102 is substantially constant from the light incident surface to the opposite surface to the light incident surface. Alternatively, the width of the trench 109 may increase from the light incident surface of the semiconductor substrate 510 toward the opposite surface thereto, and the thickness of the first insulating film 103 surrounding the anode 102 may increase from the light incident surface of the semiconductor substrate 510 toward the opposite surface.

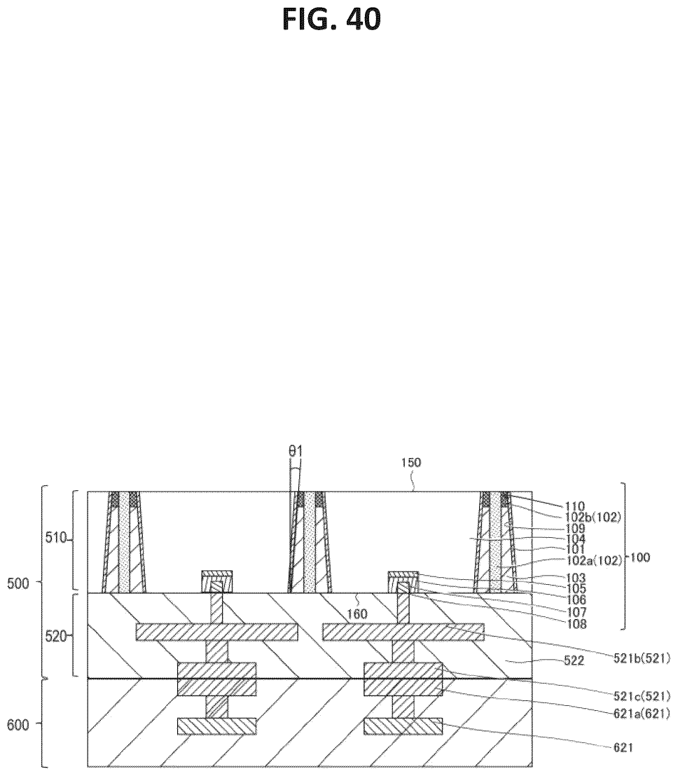

FIG. 40 is a cross-sectional view illustrating the structure of the SPAD pixel 11 according to an embodiment.

Referring to FIG. 40, the non-contact portion 102a of the anode 102 may include low light transmittance metal. The anode end portion 102b may be formed to be in contact with the light incident surface of the semiconductor substrate 510. Accordingly, the anode contact 110 may be formed in a position close to the light incident surface of the semiconductor substrate 510.

The anode 102 of each of a plurality of SPAD elements 100 may be arranged in a lattice pattern along with the trench 109. The anode 102 may be connected to power supply wiring 51 which provides the anode voltage VA from outside the element array 70. Because the anode voltage VA may be provided to each anode 102 of the SPAD elements 100 from outside the element array 70, it may not be necessary to form the anode wiring 521a in the wiring layer 520.

Because the anode wiring 521a may not be formed in the wiring layer 520, the cathode wiring 521b may extend to a region in which the trench 109 is formed. When the semiconductor substrate 510 is viewed from the side of the light incident surface in a plane view, an interstitial space of the trench 109 having a lattice pattern may be covered by the cathode wiring 521b. Because the cathode wiring 521b may function as a reflector of incident light, photon detection efficiency (PDE) may be increased.

Referring to FIG. 40, the width of the surface of the trench 109, which is in contact with the light incident surface of the semiconductor substrate 510, may be less than the width of the surface of the trench 109, which is in contact with the opposite surface to the light incident surface. The sidewall of the trench 109 may be inclined to a direction from the light incident surface to the opposite surface thereto. An angle θ1 at which the sidewall of the trench 109 is inclined with respect to the direction from the light incident surface to the opposite surface thereto may form a first angle. An angle θ2 which is an angle of the side surface of the non-contact portion 102a of the anode 102 with respect to the direction from the light incident surface to the opposite may be less than the angle θ1. The width of the trench 109 may increase from the light incident surface of the semiconductor substrate 510 toward the opposite surface thereto, and the thickness of the first insulating film 103 surrounding the anode 102 may increase from the light incident surface of the semiconductor substrate 510 toward the opposite surface thereto. Accordingly, the transfer rate of charge generated in the photoelectric conversion region 104 may be increased by increasing a potential gradient from the photoelectric conversion region 104 to an amplification region. By alleviating the electric field between the cathode and a portion of the anode 102 close to the cathode 107, noise may be reduced.

The width of the trench 109 increases from the light incident surface of the semiconductor substrate 510 toward the opposite surface to the light incident surface thereof. Alternatively, the trench 109 may be formed by connecting a first trench at the side of the light incident surface of the semiconductor substrate 510 to a second trench at the side of the opposite surface to the light incident surface. In addition, at least a portion of the second trench may be in contact with the N+-type semiconductor region 106 which is an N-type semiconductor layer of a cathode of a SPAD element 100.

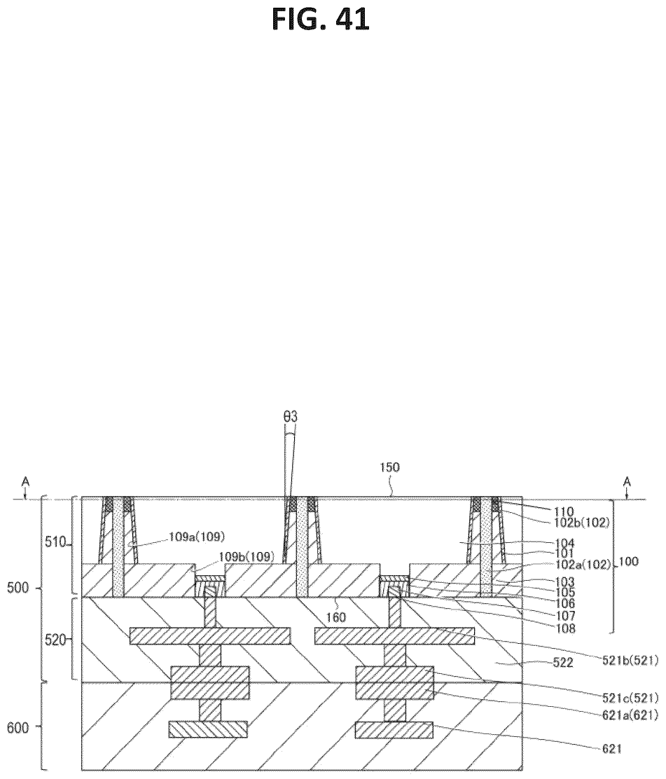

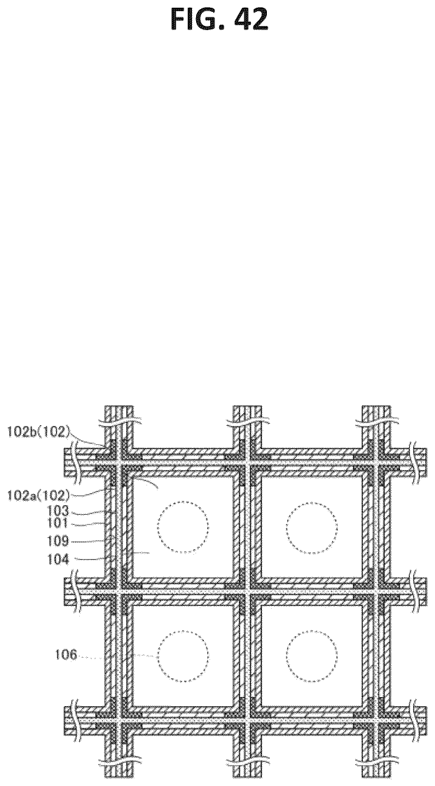

FIG. 41 is a cross-sectional view illustrating the structure of the SPAD pixel 11. FIG. 42 is a plan view of the plane A-A in FIG. 41.

Referring to FIG. 41, the non-contact portion 102a of the anode 102 may include low light transmittance metal. The anode end portion 102b may be formed to be in contact with the light incident surface of the semiconductor substrate 510. Accordingly, the anode contact 110 may be formed in a position close to the light incident surface of the semiconductor substrate 510.

Each anode 102 of a plurality of SPAD elements 100, which are arranged in a matrix form to form the element array 70, may be arranged in a lattice pattern along with the trench 109. The anode 102 may be connected to power supply wiring 51 which provides the anode voltage VA from outside the pixel array 10. Because the anode voltage VA may be provided to the anode 102 of each of the SPAD elements 100 from outside the pixel array 10, it may not be necessary to form the anode wiring 521a in the wiring layer 520.

The anode wiring 521a may not be formed in the wiring layer 520, and the cathode wiring 521b may extend to a region in which the trench 109 is formed. When the semiconductor substrate 510 is viewed from the side of the light incident surface in a plane view, an interstitial space of the trench 109 having a lattice pattern may be covered by the cathode wiring 521b. Because the cathode wiring 521b may function as a reflector of incident light, PDE may be increased.

As shown in FIG. 41, the trench 109 may be formed by connecting a first trench 109a at the side of the light incident surface of the semiconductor substrate 510 to a second trench 109b at the side of the opposite surface to the light incident surface. In addition, at least a portion of the second trench 109b may be in contact with the N+-type semiconductor region 106 of each SPAD element 100. Accordingly, the junction capacitance between the N+-type semiconductor region 106 and a P-type semiconductor layer including the P-type semiconductor region 105 may be reduced, thereby suppressing power consumption.

The width of the surface of the first trench 109a, which is in contact with the light incident surface of the semiconductor substrate 510, may be less than the width of the surface of the first trench 109a, which is connected to the second trench 109b, and the sidewall of the first trench 109a may be inclined to the direction from the light incident surface to the opposite surface thereto. The sidewall of the first trench 109a is inclined with respect to the direction from the light incident surface to the opposite surface thereto may form an angle θ3. The side surface of the non-contact portion 102a of the anode 102 with respect to the direction from the light incident surface to the opposite surface may form an angle θ4. The angle θ4 may be less than the angle θ3. The width of the first trench 109a may increase from the light incident surface of the semiconductor substrate 510 toward the opposite surface thereto, and the thickness of the first insulating film 103 surrounding the anode 102 may increase from the light incident surface toward the opposite surface. The width of the second trench 109b may be greater than the width of the first trench 109a.

The distance from the opposite surface to the light incident surface of the semiconductor substrate 510 to the bottom of the second trench 109b may be greater than the distance from the opposite surface to the light incident surface of the semiconductor substrate 510 to the PN junction of the SPAD element 100. Accordingly, the peripheral capacitance (parasitic capacitance) of the PN junction of the SPAD element 100 may be reduced.

Referring to FIG. 42, when the opposite surface to the light incident surface of the semiconductor substrate 510 is viewed from the light incident surface of semiconductor substrate 510 in a plane, the area of the N+-type semiconductor region 106 may be less than the area of the second trench 109b. Accordingly, the junction capacitance between the N+-type semiconductor region 106 and the P-type semiconductor layer including the P-type semiconductor region 105 may be reduced.

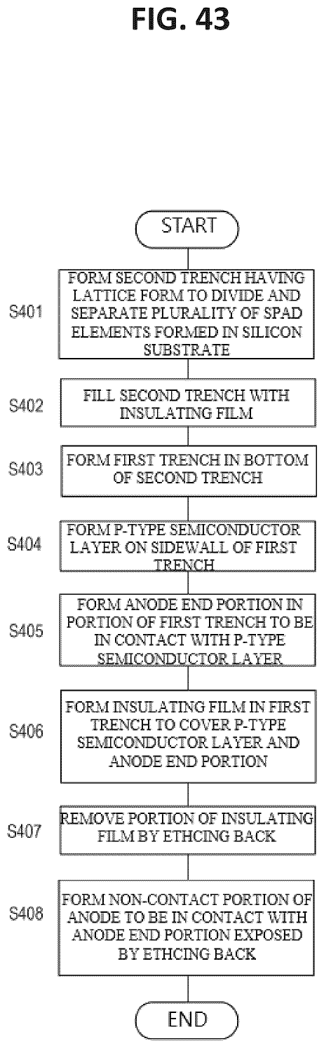

FIG. 43 is a flowchart illustrating a process for manufacturing the image sensor 1.

In the step S401, the second trench 109b having a lattice pattern may be formed in a silicon substrate to divide and separate a plurality of SPAD elements.

In the step S402, the second trench 109b may be filled with the first insulating film 103.

In the step S403, the first trench 109a may be formed in the bottom of the second trench 109b.

In the step S404, the P-type semiconductor layer 101 may be formed on the sidewall of the first trench 109a.

In the step S405, the anode end portion 102b may be formed in a portion of the first trench 109a to be in contact with the P-type semiconductor layer 101 to form an anode contact of the SPAD element 100.

In the step S406, the first insulating film 103 may be formed in the first trench 109a to cover the P-type semiconductor layer 101 and the anode end portion 102b.

In the step S407, a portion of the first insulating film 103 may be removed by etch back process.

In the step S408, the non-contact portion 102a of the anode 102 may be formed to be in contact with the anode end portion 102b, which has been exposed through the etch back process on the first insulating film 103.

The distance from the opposite surface to the light incident surface of the semiconductor substrate 510 to the bottom of the second trench 109b is greater than the distance from the opposite surface to the light incident surface of the semiconductor substrate 510 to the PN junction forming the amplification region of the SPAD element 100. Alternatively, the distance from the opposite surface to the light incident surface of the semiconductor substrate 510 to the bottom of the second trench 109b may be less than the distance from the opposite surface to the light incident surface of the semiconductor substrate 510 to the PN junction forming the amplification region of the SPAD element 100.

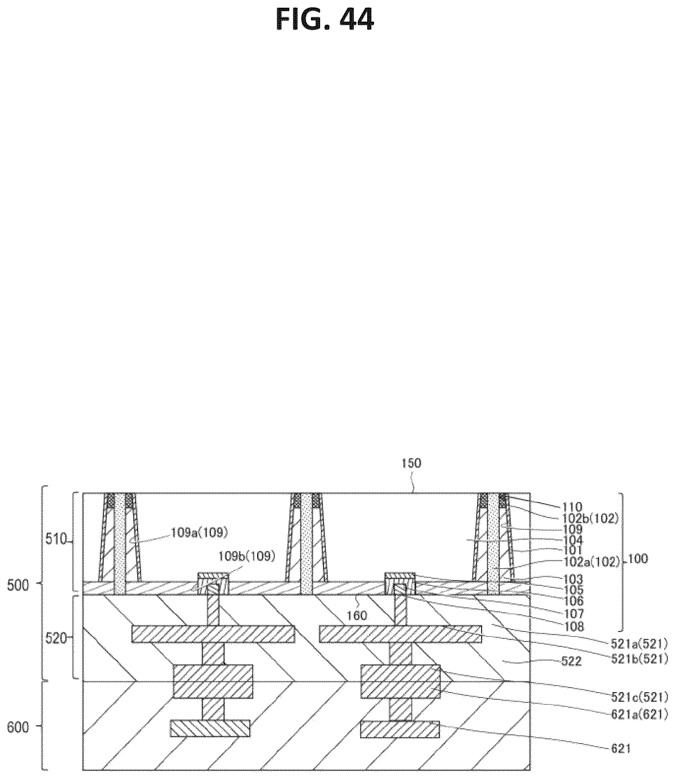

FIG. 44 is a cross-sectional view illustrating the structure of the SPAD pixel 11.

Referring to FIG. 44, the trench 109 may be formed by connecting the first trench 109a at the side of the light incident surface of the semiconductor substrate 510 to the second trench 109b at the side of the opposite surface to the light incident surface. In addition, a portion of the second trench 109b may be in contact with the N+-type semiconductor region 106 of each SPAD element 100. Accordingly, the junction capacitance between the N+-type semiconductor region 106 and a P-type semiconductor layer including the P-type semiconductor region 105 may be reduced, thereby suppressing power consumption.

The distance from the opposite surface to the light incident surface of the semiconductor substrate 510 to the bottom of the second trench 109b may be less than the distance from the opposite surface to the light incident surface of the semiconductor substrate 510 to the PN junction forming the amplification region of the SPAD element 100. Accordingly, noise may be effectively suppressed by suppressing electric field concentration at the corner of the second trench 109b.

In an image sensor having a plurality of SPAD elements formed in a substrate, each SPAD element may include a trench separating the SPAD element from another SPAD element. A P-type semiconductor layer may be formed on a sidewall of the trench, and an insulating film may cover a portion of the P-type semiconductor layer. An anode may be formed in the trench, wherein the anode includes a non-contact portion that is surrounded by the insulating film and is not in contact with the P-type semiconductor layer and an anode end portion that is in contact with the P-type semiconductor layer. Because of the distance between PN-junction and the anode, noise may be reduced, and PDE degradation may be suppressed. Furthermore, the SPAD element may be implemented in reduced layout area.

The anode contact may be closer to the first surface of the substrate than is a cathode contact of the SPAD element. Accordingly, the distance between the anode contact and the cathode contact may be increased, thereby alleviating electric field intensity. As a result, the occurrence of noise may be effectively reduced.

Because the anode end portion may be formed with P-type polysilicon, the anode contact may be formed by relatively simple process.

An element array may be formed by arranging SPAD elements in a matrix form. The anode of each of the SPAD elements may be arranged in a lattice pattern along with the trench and may be connected to power supply wiring from outside the element array. Accordingly, it is not necessary to form wiring for supplying an anode voltage in a wiring layer, thereby the area of wiring for supplying a cathode voltage to the cathode contact may be increased. Because the wiring for supplying the cathode voltage to the cathode contact may be used as a light reflector, PDE may be increased.

The anode end portion may be in contact with the first surface of the substrate, onto which light detected by the SPAD element is incident. Accordingly, the distance between the anode contact and the cathode contact may be increased, thereby alleviating the electric field between the anode contact and the cathode contact. As a result, the occurrence of noise may be effectively reduced.

By forming the anode contact only in an intersection region of the trench, the electric field intensity may be alleviated, and the occurrence of noise may be effectively suppressed.

The non-contact portion of the anode, which is not in contact with the P-type semiconductor layer, may be formed of metal. Because a light transmittance of the metal is lower than that of polysilicon, each SPAD element may be better separated from adjacent SPAD element and cross-tack between SPAD elements may be reduced.

The metal may be tungsten or aluminum.

The width of the surface of the trench, which is in contact with the first surface 150, may be less than the width of the surface of the trench, which is in contact with the second surface 160 of the substrate opposite to the first surface. The sidewall of the trench may be inclined at a first angle with respect to a direction from the first surface 150 to the second surface 160. The side surface of the anode with respect to the direction from the first surface 150 to the second surface 160 may form a second angle. The second angle may be less than the first angle. Accordingly, the thickness of the insulating film in the trench may gradually increase from the first surface 150 toward the second surface 160. Accordingly, the transfer rate of charge generated in the photoelectric conversion region 104 may be increased by increasing a potential gradient from the photoelectric conversion region 104 to an amplification region. Noise may be effectively suppressed by alleviating the electric field between the cathode and a portion of the anode 102 close to the cathode 107.

The trench may be formed by connecting a first trench, which is at the side of the first surface 150 of the substrate on which incident light is detected by the SPAD element, to a second trench, which is at the side of the second surface 160 opposite to the first surface 150 of the substrate. At least a portion of the second trench may be in contact with an N-type semiconductor layer of the cathode of the SPAD element. Accordingly, noise may be reduced by alleviation of the electric field.

The distance from the second surface 160 to the bottom of the second trench may be greater than the distance from the second surface 160 to a PN junction of the SPAD element. Accordingly, the junction capacitance between the N+-type semiconductor region 106 and the P-type semiconductor layer may be reduced, thereby suppressing power consumption.

The distance from the second surface 160 to the bottom of the second trench may be less than the distance from the second surface 160 to a PN junction forming the amplification region of the SPAD element. Accordingly, noise may be effectively suppressed by suppressing electric field concentration at the corner of the second trench.

When the second surface 160 is viewed in a plane, the area of the N-type semiconductor layer may be less than the area of the second trench. Accordingly, the junction capacitance between the N+-type semiconductor region 106 and the P-type semiconductor layer including the P-type semiconductor region 105 may be further reduced, thereby reducing power consumption.

A portion of the bottom of the trench, in which the insulating film and the cathode have been formed, may be opened, and the anode may be removed by etching while leaving a portion of the anode end portion, which is in contact with the P-type semiconductor layer. A space removed in the trench may be filled with a metal material having a low light transmittance. Accordingly, by suppressing the influence of misalignment of a mask in the replacement of the anode, the insulating film may be reliably formed.

While the inventive concept has been particularly shown and described with reference to embodiments, it will be understood that various changes in form and details may be made without departing from the spirit and scope of the following claims.

What is claimed is:

1. An image sensor comprising:
a plurality of single-photon avalanche diode (SPAD) elements formed in a substrate, and each of the plurality of SPAD elements includes:
a trench formed in a lattice pattern for separating each SPAD element from other SPAD elements of the plurality of SPAD elements;
a first semiconductor layer formed on a sidewall of the trench, the first semiconductor layer being a first conductivity type;
an insulating film formed on a portion of the first semiconductor layer; and
a first electrode formed in the trench, the first electrode including a non-contact portion and a first electrode end portion,
wherein the non-contact portion is surrounded by the insulating film and not in contact with the first semiconductor layer, and the first electrode end portion is connected with the non-contact portion and in contact with the first semiconductor layer.

2. The image sensor of claim 1, wherein a first distance from a first contact formed between the electrode end portion and the first semiconductor layer to a first surface of the substrate is shorter than a second distance from a second contact formed on a second electrode of the SPAD element to the first surface of the substrate, wherein the first surface of the substrate receives incident light detected by each of the plurality of the SPAD elements.

3. The image sensor of claim 1, wherein the first electrode end portion includes polysilicon of the first conductivity type.

4. The image sensor of claim 1, wherein the plurality of SPAD elements are arranged in a lattice pattern to form an array of the SPAD elements, and the first electrode is arranged in the lattice pattern along the trench and is connected to a power supply supplied from outside the array of the SPAD elements.

5. The image sensor of claim 1, wherein the first electrode end portion is exposed to a first surface of the substrate, wherein the first surface of the substrate receives incident light that is detected by the plurality of SPAD elements.

6. The image sensor of claim 1, wherein a first contact formed between the electrode end portion and the first semiconductor layer is arranged only in an intersection region of the trench.

7. The image sensor of claim 1, wherein the non-contact portion of the first electrode includes metal, and is exposed to a first surface of the substrate, in which a light transmittance of the metal is lower than that of polysilicon, and the first surface of the substrate receives incident light that is detected by the plurality of SPAD elements.

8. The image sensor of claim 7, wherein the metal includes one of tungsten and aluminum.

9. The image sensor of claim 7, wherein a first width of the trench at the first surface of the substrate is less than a second width of the trench at a second surface opposite to the first surface of the substrate, wherein the sidewall of the trench is inclined at a first angle with respect to a direction from the first surface to the second surface, and the first angle is larger than a second angle of a side surface of the first electrode with respect to the direction from the first surface to the second surface.

10. The image sensor of claim 1, wherein the first conductivity type is positive type.

11. The image sensor of claim 1, wherein the trench is formed by connecting a first trench to a second trench, the first trench being close to a first surface of the substrate, and the second trench being close to a second surface of the substrate opposite to the first surface, wherein the first surface of the substrate receives incident light, and the second surface of the substrate includes a second semiconductor layer which has a second conductivity type different from the first conductivity type and forms a second electrode of each of the plurality of SPAD elements.

12. The image sensor of claim 11, wherein a first distance from the second surface of the substrate to a bottom of the second trench is longer than a second distance from the second surface of the substrate to a junction formed by the first semiconductor layer and the second semiconductor layer, and the junction forms an amplification region of each of the plurality of SPAD elements.

13. The image sensor of claim 11, wherein a first distance from the second surface of the substrate to a bottom of the second trench is shorter than a second distance from the second surface of the substrate to a junction formed by the first semiconductor layer and the second semiconductor layer, and the junction forms an amplification region of each of the plurality of SPAD elements.

14. The image sensor of claim 11, wherein an area of the second semiconductor layer is less than an area of the second trench when viewed in a plane from the second surface of the substrate.

15. A method of manufacturing an image sensor including a plurality of single-photon avalanche diode (SPAD) elements, the method comprising:
forming a trench in a lattice pattern for separating each of the plurality of single-photon avalanche diode (SPAD) elements formed in a substrate;
forming a first semiconductor layer on a sidewall of the trench, in which the first semiconductor layer has a first conductivity type;
forming an insulating film in the trench, the insulating film covering a portion of the first semiconductor layer;
forming a non-contact portion of a first electrode in a portion of the trench, the non-contact portion of the first electrode being in contact with the insulating film; and
forming a first electrode end portion in contact with the first semiconductor layer and the non-contact portion of the first electrode, wherein a first contact is formed between the electrode end portion and the first semiconductor layer.

16. A method of manufacturing an image sensor including a plurality of single-photon avalanche diode (SPAD) elements, the method comprising:
forming a trench in a lattice pattern for separating each of the plurality of single-photon avalanche diode (SPAD) elements formed in a substrate;
forming a first semiconductor layer on a sidewall of the trench, in which the first semiconductor layer has a first conductivity type;
forming a first electrode end portion in a portion of the trench in contact with the first semiconductor layer, in which a first contact is formed between the electrode end portion and the first semiconductor layer;
forming an insulating film in the trench, the insulating film covering a portion of the first semiconductor layer and the first electrode end portion;
exposing the first electrode end portion by etching back the insulating film; and
forming a non-contact portion of a first electrode, the non-contact portion being in contact with the first electrode end portion.

17. The method of claim 16, further comprising:
opening a portion of a bottom of the trench and removing the non-contact portion of the first electrode through etching process, while leaving a portion of the first electrode end portion in contact with the first semiconductor layer; and
filling the removed space with a metal material in which a light transmittance of the metal material is lower than that of polysilicon.

18. The method of claim 17, wherein the method further comprises planarizing the metal material and forming an anti-reflective layer on the planarized metal material.

19. The method of claim 16, wherein the forming the trench includes:
forming a first portion of the trench;
filling the first portion of the trench with an insulating film; and
forming the second portion of the trench at a bottom of the first portion of the trench,
forming the first semiconductor layer on a sidewall of the first trench; and
forming the first electrode end portion being in contact with the first semiconductor layer, in which the first contact is formed between the electrode end portion and the first semiconductor layer.

20. The method of claim 19, wherein a width of the first portion of the trench is greater than a width of the second portion of the trench.
